(19) United States
(12) Patent Application Publication
(10) Pub. No.: US 2025/0194281 A1
(43) Pub. Date: Jun. 12, 2025

(54) MULTI-DIE CMOS IMAGE SENSOR INTEGRATED CIRCUIT DEVICE

(71) Applicant: Taiwan Semiconductor Manufacturing Company, Ltd., Hsinchu (TW)

(72) Inventors: Kuo-Chin Huang, Yilan City (TW); Tzu-Jui Wang, Fengshan City (TW); Chen-Jong Wang, Hsin-Chu (TW); Dun-Nian Yaung, Taipei City (TW)

(21) Appl. No.: 18/401,747

(22) Filed: Jan. 2, 2024

Related U.S. Application Data
(60) Provisional application No. 63/608,412, filed on Dec. 11, 2023.

(51) Int. Cl. H01L 27/146; H01L 21/768; H01L 23/00; H01L 23/48

(52) U.S. Cl. CPC H10F 39/809; H01L 21/76898; H01L 23/481; H01L 24/08; H01L 24/80; H10F 39/018; H10F 39/8037; H01L 2224/08145; H01L 2224/80895; H01L 2224/80896

(57) ABSTRACT

Some embodiments relate to an integrated circuit device including upper and lower layers. The upper layer includes pixel cells that each include a photodetector and a transfer transistor to transfer electrical charge collected at the photodetector. The upper layer also includes first conductive pads at a lower surface of the upper layer, each of the first pads carrying an indication of the electrical charge transferred by the transfer transistor of one or more of the pixel cells. The lower layer includes second conductive pads at an upper surface of the lower layer, the upper surface of the lower layer lying adjacent the lower surface of the upper layer. Each of the second pads directly contact a corresponding one of the first pads. The lower layer also includes a processing circuit conductively coupled to the second pads and configured to process signals carried via the first and second pads.

### REFERENCE TO RELATED APPLICATION

This Application claims the benefit of U.S. Provisional Application No. 63/608,412, filed on Dec. 11, 2023, the contents of which are hereby incorporated by reference in their entirety.

### BACKGROUND

Use of a complementary metal-oxide-semiconductor (CMOS) image sensor (CIS) in an electronic device often involves the utilization of various additional circuit resources to render signals generated by the CIS useful. For example, in addition to a pixel array for receiving light, the CIS may be accompanied by one or more of timing circuitry for measuring an amount of the received light, image processing circuitry to generate the resulting image data, memory for storing the image data, communication circuitry for providing the image data to another circuit or device, and power circuitry that may distribute, filter, and/or otherwise process electrical power for the CIS and associated circuits. Such circuits may be incorporated within a single CIS integrated circuit (IC) device to reduce footprint consumed by the device on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic exploded isometric view of some embodiments of a CIS multi-die IC device, according to the present disclosure.

FIG. 2A illustrates a block diagram of some embodiments of a pixel cell employable in a CIS multi-die IC device, according to the present disclosure.

FIG. 2B illustrates a schematic diagram of some embodiments of a pixel cell employable in a CIS multi-die IC device, according to the present disclosure.

FIG. 3A illustrates a schematic/block diagram of some embodiments of a pixel cell, a per-pixel circuit, an in-pixel circuit, and an application-specific integrated circuit (ASIC) employable in a three-layer CIS IC device, according to the present disclosure.

FIG. 3B illustrates a schematic/block diagram of some embodiments of a pixel cell, a per-pixel circuit, an in-pixel circuit, and an ASIC employable in a two-layer CIS IC device, according to the present disclosure.

FIGS. 4A through 4D illustrate block diagrams of some embodiments of a four-layer CIS IC device, according to the present disclosure.

FIGS. 5A through 5E illustrate structural cross-sectional views of some embodiments of a four-layer CIS IC device corresponding to the block diagrams of FIGS. 4A through 4D, according to the present disclosure.

FIGS. 6A through 6I illustrate cross-sectional side views of some embodiments of a CIS multi-die IC device at various stages of manufacture, according to the present disclosure.

FIG. 7 illustrates a methodology of forming a CIS multi-die IC device, in accordance with some embodiments.

FIGS. 8A through 8I illustrate schematic cross-sectional side views of some embodiments of a four-layer CIS multi-die IC device at various stages of manufacture, according to the present disclosure.

FIGS. 9A through 9H illustrate schematic cross-sectional side views of some embodiments of another four-layer CIS multi-die IC device at various stages of manufacture, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Given the different types of circuits that may be employed in association with a CIS to capture one or more images, incorporation of such circuits with a CIS within a single IC device may present a significant design and fabrication challenge. For example, a CIS IC device may include a pixel array that calls for a specialized fabrication process, memory for storing digital image data that involves memory technology, power circuitry that may be implemented using a thick oxide process, and complex image processing circuitry that may be employed using small, fast logic circuit elements. Consequently, CIS IC devices may include various types of circuitry that are difficult to integrate within a single device in a manner that provides enhanced pixel performance while reducing device cost.

To address these issues, the present disclosure provides some embodiments of a multi-die CIS IC device. In some embodiments, an IC device may include at least two IC layers (e.g., an upper IC layer and a lower IC layer). The upper IC layer may include a plurality of pixel cells, where each pixel cell includes a photodetector (e.g., a photodiode) and a transfer transistor electrically coupled to the photodetector. The transfer transistor may be configured to transfer electrical charge collected at the photodetector. The upper IC layer may also include a first plurality of conductive pads at a lower surface of the upper IC layer, where at least some of the first plurality of conductive pads may carry an indication of the electrical charge transferred by the transfer transistor of one or more of the plurality of pixel cells.

The lower IC layer may include a second plurality of conductive pads at an upper surface of the lower IC layer, where each of the second plurality of conductive pads directly contacts a corresponding one of the first plurality of conductive pads. The lower IC layer may also include a processing circuit conductively coupled to the second plurality of pads. The processing circuit may be configured to process signals carried via the first and second pluralities of conductive pads. In some embodiments, one or more additional lower IC layers may be employed to carry other processing circuits that facilitate processing signals or data associated with the pixel cells.

Accordingly, use of some embodiments may provide a CIS IC device by which different functional circuits may reside on different IC layers that are bonded together. In some embodiments, by organizing different circuits that are fabricated using different technologies (e.g., technology nodes of different circuit geometries and capabilities) onto different wafers or dies, fabrication of each individual layer is simplified compared to providing all such technologies on a single wafer. In addition, in some embodiments, such separation of circuitry among the layers, such as employing pixel cells along or in conjunction with a limited number of other circuits, may facilitate reduction of the area consumed by each pixel, thus possibly resulting in a smaller overall CIS IC device, greater image resolution, and/or other improvements. Accordingly, the resulting CIS IC device may provide improved pixel performance and/or reduced device cost relative to previously available alternatives.

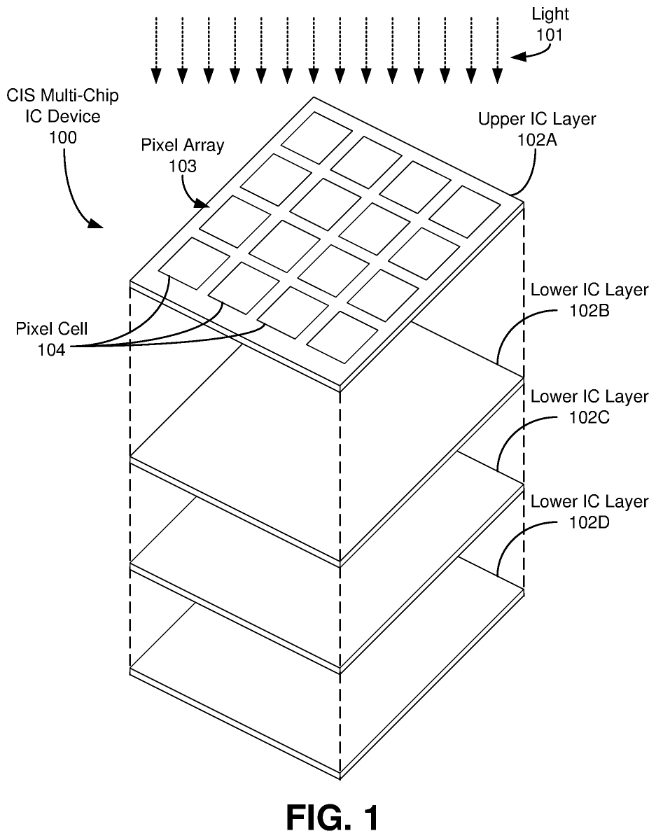

FIG. 1 illustrates a schematic exploded isometric view of some embodiments of a CIS multi-die IC device 100, according to the present disclosure. CIS multi-die IC device 100 (also referred to as CIS IC device 100 below) includes an upper IC layer 102A and one or more lower IC layers 102B, 102C, and 102D that are bonded together. In some embodiments, upper IC layer 102A and lower IC layers 102B, 102C, and 102D (e.g., first lower IC layer 102B, second lower IC layer 102C, and third lower IC layer 102D) are bonded at the wafer level (e.g., prior to singulation into individual ICs). In other embodiments, one or more of upper IC layer 102A and lower IC layers 102B, 102C, and 102D are bonded to each other according to die-to-wafer or flip chip bonding.

In some embodiments, upper IC layer 102A includes a plurality of pixel cells 104 that may be organized as a pixel array 103 that is sensitive to light 101 impacting an upper surface of upper IC layer 102A. Further, in some embodiments, as described in greater detail below, upper IC layer 102A may include additional circuitry that may be incorporated with pixel cells 104. Additionally, one or more lower IC layers 102B, 102C and 102D may include processing circuits (not shown in FIG. 1) that may be collectively employed (e.g., to generate image data representing light 101 received at pixel cells 104). In some embodiments, by organizing pixel cells 104 and other circuitry among the different IC layers 102A-102D as described below, each such IC layer may be constructed using a fabrication process or technology node that is appropriate for the associated circuitry. Accordingly, enhanced pixel performance and/or device cost reduction for the resulting CIS IC device 100 relative to other CIS IC devices may be achieved.

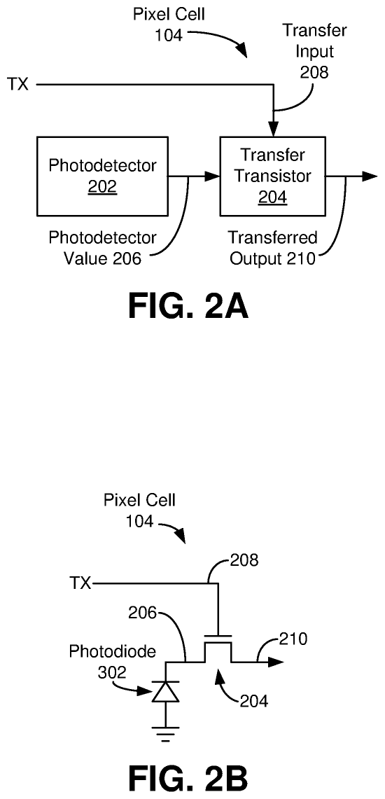

FIG. 2A illustrates a block diagram of some embodiments of pixel cell 104 employable in CIS multi-die IC device 100, according to the present disclosure. In such embodiments, pixel cell 104 may include a photodetector 202 that provides a photodetector value 206 (e.g., an amount of electrical charge) and a transfer transistor 204 that forwards the value as a transferred output 210 under the control of a transfer input 208. In some embodiments, and as described below, photodetector 202 may include a photodiode 302, such as a PIN diode. However, in other embodiments, photodetector 202 may be a phototransistor or other type of photodetector. In some embodiments, pixel cells 104 may be apportioned to detect different wavelength ranges (e.g., grouped as red, blue, and green pixels) by being associated with corresponding color filters (not shown in the various drawings provided herewith) positioned over upper IC layer 102A of FIG. 1. Also, while photodetector 202 may be sensitive to a particular visible band or range, or set of ranges, of visible light, photodetector 202 may be sensitive to non-visible light (e.g., infrared light) in other embodiments.

FIG. 2B illustrates a schematic diagram of some embodiments of pixel cell 104 employable in CIS multi-die IC device 100, according to the present disclosure. As depicted in FIG. 2B, pixel cell 104 may include a photodiode 302 with a grounded (e.g., connected to a source voltage VSS) anode and a cathode providing photodetector value 206 to a first source/drain connection of transfer transistor 204. Further, transfer transistor 204 may transfer photodetector value 206 to transferred output 210 at a second source/drain region in response to a transfer input 208 (also marked as “TX” in FIG. 2B) at a gate input of transfer transistor 204. However, other configurations for photodetector 202 and transfer transistor 204 of FIG. 2A may be employed in other embodiments.

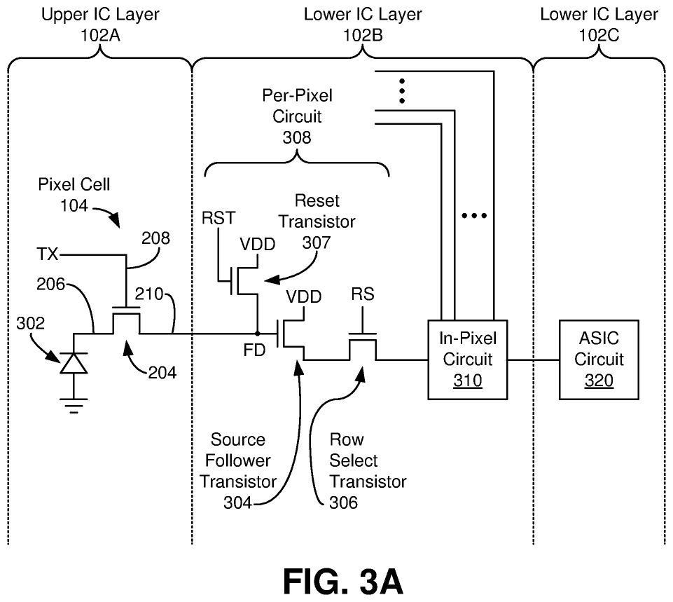

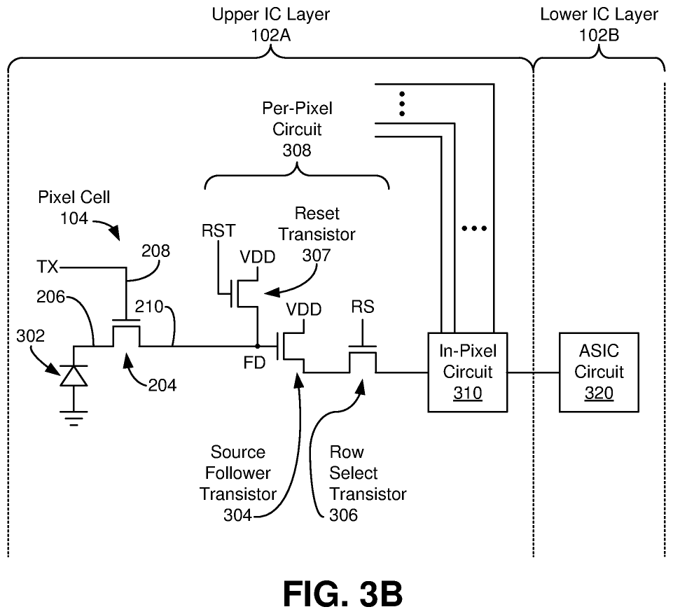

FIGS. 3A and 3B illustrate embodiments in which pixel cell 104 and associated processing circuits may be organized or apportioned among two or three IC layers of a CIS IC device to facilitate improved device performance and/or cost. For example, FIG. 3A illustrates a schematic/block diagram of some embodiments of pixel cell 104, a per-pixel circuit 308, an in-pixel circuit 310, and an application-specific integrated circuit (ASIC) 320 employable in a three-layer CIS multi-die IC device, according to the present disclosure. As shown, pixel cells 104, including a photodetector (e.g., photodiode 302) and transfer transistor 204, as described above, are included in upper IC layer 102A. Further, per-pixel circuit 308 and in-pixel circuit 310 are located on first lower layer IC layer 102B, and ASIC circuit 320 is positioned on second lower IC layer 102C.

FIG. 3B illustrates a schematic/block diagram of some embodiments of pixel cell 104, per-pixel circuit 308, in-pixel circuit 310, and ASIC 320 employable in a two-layer CIS multi-die IC device, according to the present disclosure. More specifically, as illustrated in FIG. 3B, pixel cell 104, per-pixel circuit 308, and in-pixel circuit 310 are located in upper IC layer 102A, while ASIC 320 is provided in lower IC layer 102B.

While a single pixel cell 104 and a single per-pixel circuit 308 are depicted in FIGS. 3A and 3B, at least some embodiments described herein include a plurality of pixel cells 104 (e.g., organized into rows and columns of pixel array 103 of FIG. 1) and a plurality of per-pixel circuits 308, where each per-pixel circuit 308 is electrically coupled to a corresponding one of pixel cells 104. As also shown in FIGS. 3A and 3B, each of the per-pixel circuits 308 may be coupled to in-pixel circuit 310.

In some embodiments, per-pixel circuit 308 is configured to provide a timed indication of the electrical charge (e.g., transferred output 210) transferred from photodiode 302 via transfer transistor 204 for a corresponding pixel cell 104. For example, in some embodiments, per-pixel circuit 308 may include a source follower transistor 304, a row-select transistor 306, and a reset transistor 307. Source follower transistor 304 may be electrically coupled to transfer transistor 204 (e.g., at a gate connection of source follower transistor 304) and configured to buffer transfer transistor 204 (e.g., transferred output 210) from another circuit (e.g., within in-pixel circuit 310, such as a column bus). In some embodiments, source follower transistor 304 may be configured as an amplifier for transferred output 210. In some examples, the gate connection to source follower transistor 304 may be viewed as a floating diffusion (marked “FD” in FIGS. 3A and 3B) at which electrical charge is provided prior to being transferred to in-pixel circuit 310.

Reset transistor 307 may also be coupled to source follower transistor 304 (e.g., at a gate connection of source follower transistor 304) to reset the electrical charge being transferred from photodiode 302 by transfer transistor 204 under the control of a reset (“RST”) signal (e.g., by raising the gate connection of source follower transistor to a drain (supply) voltage VDD).

In some embodiments, row select transistor 306 may be configured to forward the electrical charge of pixel cell 104 via source follower transistor 304 to in-pixel circuit 310 in a timed manner based on a row select (“RS”) signal (e.g., driving a gate connection of row select transistor 306). Also, in some embodiments, row select transistor 306, by way of drain/source connections, may couple source follower transistor 304 to a column bus of in-pixel circuit 310.

In-pixel circuit 310, in some embodiments, may process the plurality of timed indications of electrical charge received by source follower transistor 304 (e.g., for multiple columns of pixel cells 104 on a row-by-row basis) to at least partially generate analog image data represented by the electrical charges stored in pixel cells 104. In some embodiments, in-pixel circuit 310 may generate the signals (e.g., TX, RST, and RS signals) controlling pixel cell 104 and per-pixel circuit 308, as described above. More broadly, in some embodiments, in-pixel circuit 310 may include one or more of column-level circuitry, column bus signal lines (e.g., one signal line per column), one or more bias transistors (e.g., to bias a voltage level of one or more column bus signal lines), a column controller, and a row controller.

ASIC circuit 320, in some embodiments, may include any additional circuitry (e.g., one or more analog-to-digital (ADC) converters, memory, image signal processors (ISPs), communications circuitry, power circuitry, and/or the like) that may be employed as part of, or in connection with, a CIS IC device. Examples of circuitry that may be included in ASIC circuit 320 are described in greater detail below.

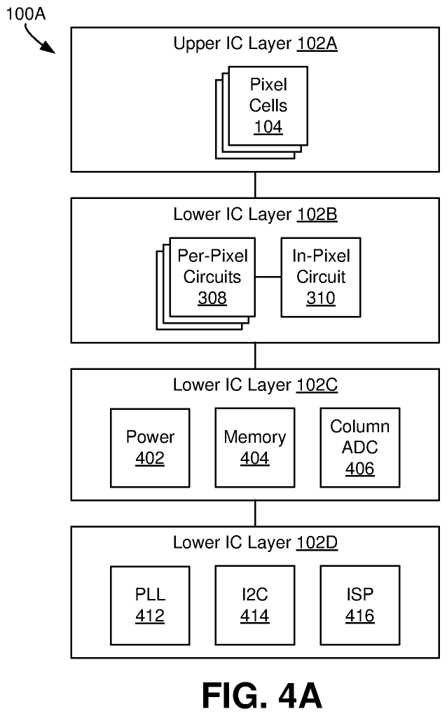

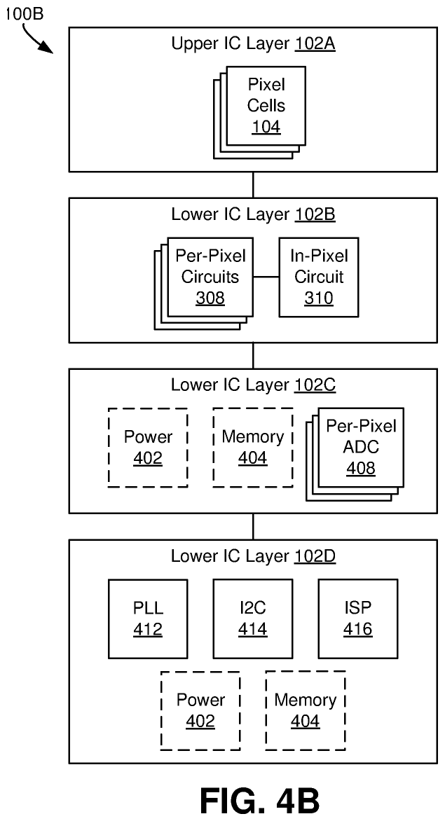

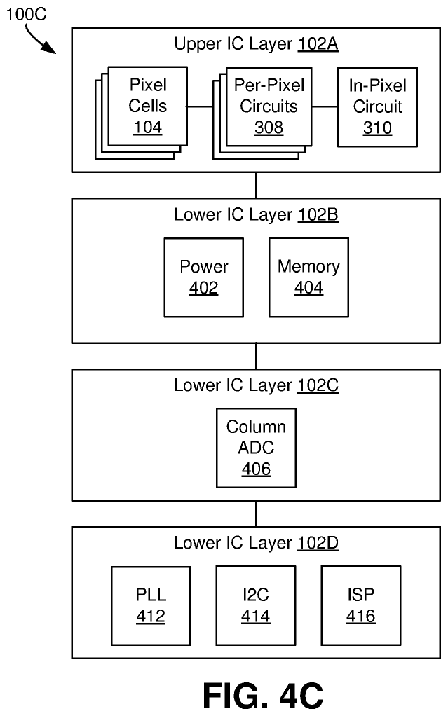

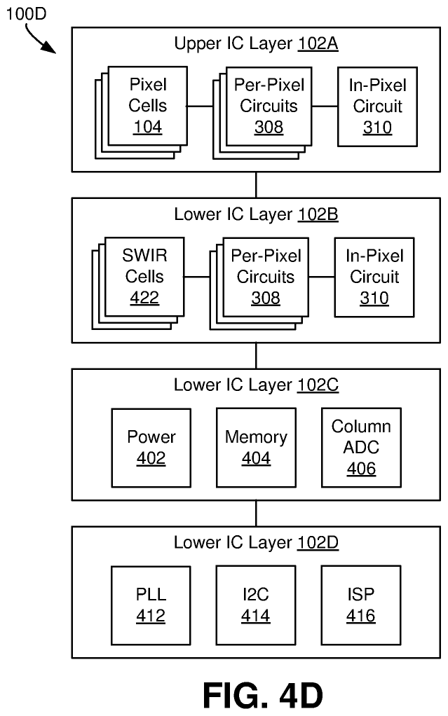

FIGS. 4A through 4D illustrate block diagrams of some embodiments of a four-layer CIS multi-die IC device, according to the present disclosure. For example, in FIG. 4A, CIS IC device 100A includes upper IC layer 102A that includes pixel cells 104 and further includes first lower IC layer 102B that includes per-pixel circuits 308 and in-pixel circuit 310 (e.g., as discussed above in connection with FIG. 3A). Additionally, in some embodiments, CIS IC device 100A also includes second lower IC layer 102C that may include power circuitry 402 (e.g., to provide, filter, and/or distribute power for CIS IC device 100A), one or more memories 404 (e.g., to store digital image data represented in pixel cells 104), and/or column ADCs 406 (to convert the timed indications for the electrical charges of pixel cells 104 to digital image data for each column of pixel cells 104). Also included in CIS IC device 100A, in some embodiments, third lower IC layer 102D may include a phased-lock loop (PLL) 412 (e.g., to generate timing signals for in-pixel circuit 310 and other portions of CIS IC device 100A), Inter-Integrated Circuit (I2C) 414 (e.g., for providing communication between CIS IC device 100A and other circuits or systems), and ISP 416 (e.g., for processing digital image data generated from the electrical charges in pixel cells 104).

In some embodiments, the partitioning of the above-described functions among the upper IC layer 102A and the various lower IC layers 102B, 102C, and 102D may simplify fabrication of each separate IC layer 102A-102D by reducing the number of different process technologies that are required to generate each separate one of the IC layers. For example, in FIG. 4A, upper IC layer 102A may be fabricated using at least a specialized process directed to creating pixel cells 104 (e.g., to minimize the footprint of each pixel cell 104). Further, in some embodiments, first lower IC layer 102B may be fabricated using at least a low-power technology node (e.g., to implement per-pixel circuits 308 and in-pixel circuit 310). In some embodiments, second lower IC layer 102C may be implemented using at least a high-voltage (e.g., thick oxide) technology (e.g., to accommodate the relatively high-level voltages of power circuitry 402 and/or column ADCs 406). Further, in some embodiments, third lower IC layer 102D may be fabricated using at least a short-dimension, high-performance (e.g., fast-switching) technology (e.g., to facilitate high operating speeds for at least ISP 416). In some embodiments, more than one technology node may be employed on one or more IC layers 102A-102D. However, employing more than one IC layer may aid in preventing use of three or more process technology nodes on any single IC layer.

In CIS IC device 100B of FIG. 4B, the various IC layers 102A-102D, as well as the particular functions assigned to each IC layer, are similar to those discussed above in connection with CIS IC device 100A of FIG. 4A, with the exception of per-pixel ADCs 408 (also known as pixel-level ADCs) being employed in CIS IC device 100B instead of column ADCs 406 in CIS IC device 100A. In some embodiments, each column ADC 406 of FIG. 4A may perform analog-to-digital conversion for a corresponding column signal line of a column signal line bus, while each per-pixel ADC 408 of FIG. 4B may perform analog-to-digital conversion for a corresponding pixel cell 104. Accordingly, in some embodiments, the electrical charge of each of pixel cells 104 may be collected and processed concurrently, instead of on a row-by-row basis using column ADCs 406. As a result, in-pixel circuit 310 may be configured to receive timed indications of the electrical charges from all pixel cells 104 simultaneously, thus possibly facilitating an accelerated frame rate for operating pixel cells 104. Additionally, in some embodiments, due to the incorporation of per-pixel ADCs 408 in second lower IC layer 102C, the presence of other functions (e.g., power 402, memory 404, or other functions) within second lower IC layer 102C may cause the area of second lower IC layer 102 to greatly increase. Consequently, the use of third lower IC layer 102D may enable the incorporation of one or more of power 402, memory 404, PLL 412, 12C 414, and/or ISP 416 therein, thus possibly allowing CID IC device 100B to retain a footprint that substantially matches or slightly exceeds the area occupied by pixel cells 104 of upper IC layer 102A.

In FIG. 4C, a CIS IC device 100C may be arranged such that pixel cells 104, per-pixel circuits 308, and in-pixel circuit 310 may be implemented in upper IC layer 102A. In such embodiments, memory 404 (e.g., random-access memory (RAM), such as dynamic random-access memory (DRAM), resistive RAM (R-RAM), magneto-resistive RAM (M-RAM), or the like) for storing image data generated from pixel cells 104 may be implemented on a separate IC layer from column ADCs 406, thus possibly improving the operation of either or both memory 404 and column ADCs 406. For example, in embodiments indicated in FIG. 4C, first lower IC layer 102B may include power circuitry 402 and memory 404, while second lower IC layer 102C may include column ADCs 406. In some embodiments, third lower IC layer 102D may include similar processing circuits to those of FIGS. 4A and 4B (e.g., PLL 412, 12C 414, and ISP 416).

CIS IC device 100D of FIG. 4D may employ a second pixel cell array that includes pixel cells that capture a different range of wavelengths (e.g., infrared wavelengths). In some embodiments, upper IC layer 102A and first lower IC layer 102B may be organized in a similar manner such that pixel cells 104 (e.g., configured for visible light), along with per-pixel circuits 308 and in-pixel circuit 310 may be located in upper IC layer 102A, while shortwave infrared (SWIR) pixel cells 422, along with their corresponding per-pixel circuits 308 and in-pixel circuit 310, may be positioned in first lower IC layer 102B. In some embodiments, a detection wavelength for SWIR pixel cells 422 (e.g., a wavelength greater than 1000 nanometers (nm)) may be longer than an absorption limitation for a material included in upper IC layer 102A and lower IC layer 102B (e.g., silicon) to facilitate transmission of SWIR light through upper IC layer 102A to first lower IC layer 102B. Also, in some embodiments, SWIR pixel cells 422 may be laterally offset from conductive (e.g., metal) structures employed in upper IC layer 102A to facilitate detection of SWIR light by SWIR pixel cells 422.

Further, in some embodiments, second lower IC layer 102C (e.g., hosting power circuitry 402, memory 404, and column ADCs 406) and third lower IC layer 102D (e.g., carrying PLL 412, 12C 414, and ISP 416) may be configured in a manner similar to that shown in FIGS. 4A and 4B.

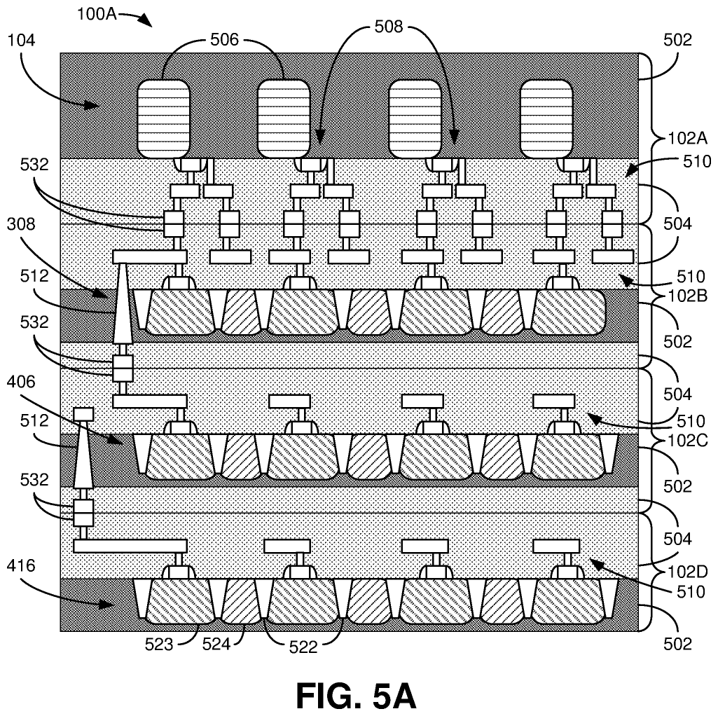

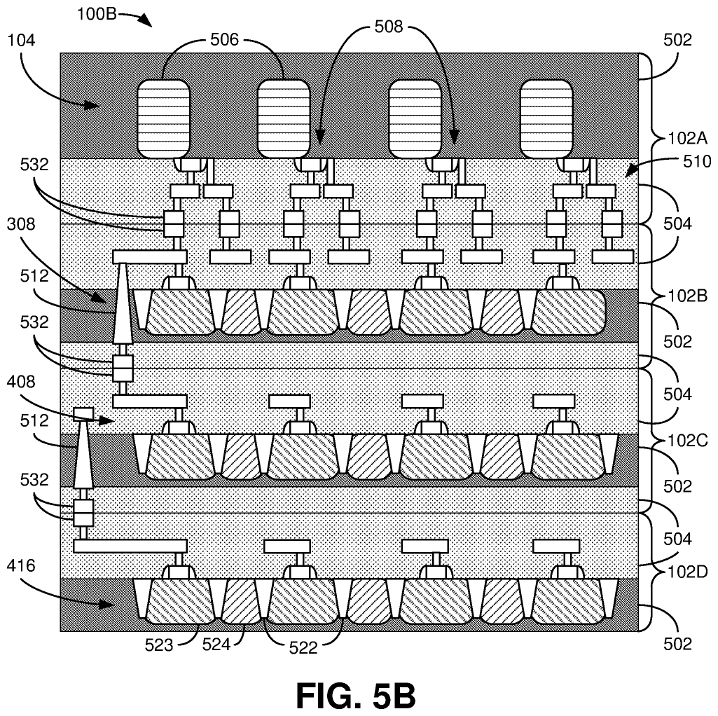

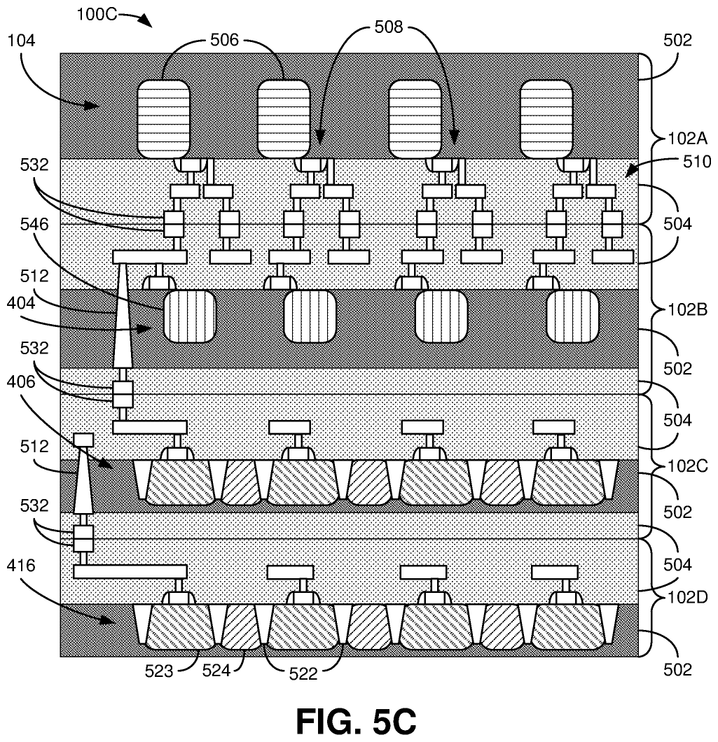

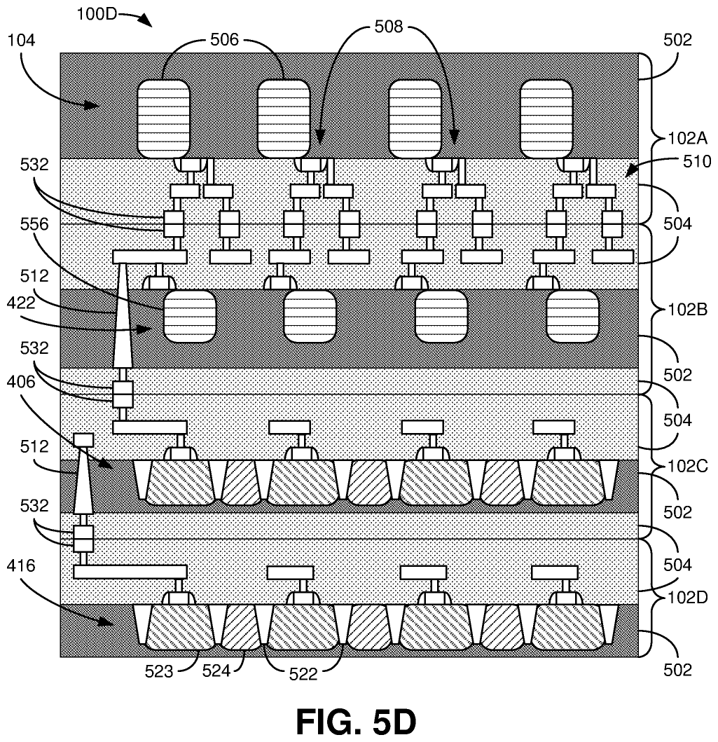

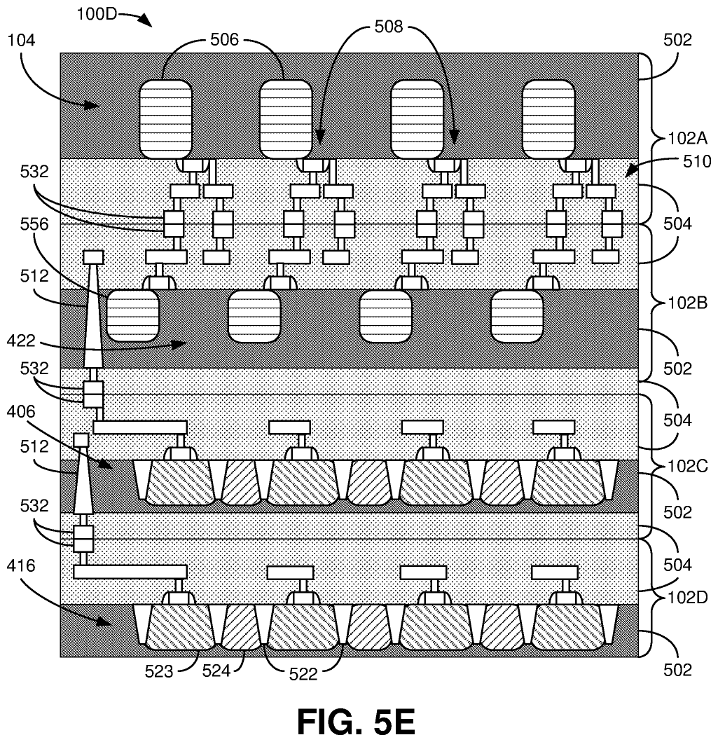

FIGS. 5A through 5D illustrate structural cross-sectional views of some embodiments of a four-layer CIS multi-die IC device 100A-100D corresponding to the block diagrams of FIGS. 4A through 4D, respectively, according to the present disclosure. For example, in each of FIGS. 5A through 5D, upper IC layer 102A and lower IC layers 102B, 102C, and 102D are bonded together in the spatial order depicted in FIGS. 4A through 4D, respectively. In addition, FIG. 5E illustrates a structural cross-sectional view of some embodiments of a four-layer CIS multi-die IC device 100E associated with FIGS. 4D and 5D.

Beginning with upper IC layer 102A, a substrate 502 (e.g., a silicon substrate) may include a plurality of photosensitive regions 506, each of which may form a corresponding photodetector (e.g., photodiode 302 of FIGS. 3A and 3B) with the surrounding regions of substrate 502. In some embodiments, photosensitive regions 506 are formed proximate a lower surface of substrate 502 adjacent to which a dielectric layer 504 is disposed. Further, in some embodiments, within dielectric layer 504 proximate the lower surface of substrate 502, transfer transistors 508 (e.g., including at least one source/drain connection, a gate oxide material with a connecting metal contact, and possibly a spacer structure) may be coupled with photosensitive regions 506 to form pixel cells 104.

In some embodiments, dielectric layer 504 of upper IC layer 102A may include a plurality of conductive pads 532 at a lower surface of dielectric layer 504 opposite substrate 502. Further, dielectric layer 504 of upper IC layer 102A may include a conductive structure 510 electrically connecting pixel cells 104 to conductive pads 532. In some embodiments, conductive structure 510 may include conductive (e.g., metal) layers interconnected with conductive (e.g., metal) vias. Also, in some embodiments, conductive pads 532 may include metal (e.g., copper, aluminum, or the like) or another conductive material.

In some embodiments, each of dielectric layer 504, as well as other dielectric layers described herein, may include one or more dielectric materials, including, but not limited to, silicon oxide (SiOₓ) (e.g., silicon oxide (SiO₂)), silicon nitride (SiN), silicon carbide (SiC), carbon doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like.

First lower IC layer 102B, in turn, may include its own substrate 502 (e.g., a silicon substrate) and two dielectric layers 504. Within first lower IC layer 102B, substrate 502 may include at least a portion of a first processing circuit (e.g., plurality of per-pixel circuits 308 of FIGS. 3A and 3B). At an upper surface of a first dielectric layer 504 of first lower IC layer 102B proximate a lower surface of dielectric layer 504 of upper IC layer 102A may be a plurality of conductive pads 532, where each of the conductive pads 532 of the first dielectric layer 504 of first lower IC layer 102B is in direct contact with a corresponding conductive pad 532 of dielectric layer 504 of upper IC layer 102A. Also, a conductive structure 510 may be disposed within first dielectric layer 504 of first lower IC layer 102B to electrically couple conductive pads 532 of first dielectric layer 504 with per-pixel circuits 308.

Disposed at a lower surface of substrate 502 of first lower IC layer 102B is second dielectric layer 504 of first lower IC layer 102B. At a lower surface of second dielectric layer 504 is disposed a plurality of conductive pads 532. (FIG. 5A depicts only one such conductive pad 532 at the lower surface of second dielectric layer 504 for clarity of presentation.) In some embodiments, through-substrate vias (TSVs) 512 are disposed in substrate 502 of first lower IC layer 102B and into first dielectric layer 504 to electrically couple conductive structure 510 of first dielectric layer 504 with conductive pads 532 of second dielectric layer 504 of first lower IC layer 102B.

As also shown in FIG. 5A, second lower IC layer 102C and third lower IC layer 102D are constructed in a manner similar to first lower IC layer 102B. More specifically, each of second lower IC layer 102C and third lower IC layer 102D includes a substrate 502 and a first (upper) dielectric layer 504. Second lower IC layer 102C also includes a second (lower) dielectric layer 504. Second lower IC layer 102C is depicted as including circuitry for column ADCs 406 and third lower IC layer 102D is shown as including circuitry for ISP 416. Also, each of second lower IC layer 102C and third lower IC layer 102D includes conductive structures 510 for coupling the enclosed processing circuits of the corresponding IC layer to conductive pads 532 to electrically connect to corresponding conductive pads 532 of the next higher IC layer. Second lower IC layer 102C also includes TSVs 512 disposed in substrate 502 to couple conductive structure 510 to conductive pads 532 at a lower surface of second (lower) dielectric layer 504 of second lower IC layer 102C.

While each of IC layers 102A-102D is shown as including a particular circuit function (e.g., ISP 416 of third lower IC layer 102D), other functions illustrated in FIG. 3A may also be included in their respective IC layers 102A-102D of CIS IC device 100A of FIG. 5A, but are not shown in FIG. 5A to simplify and focus the above discussion. FIGS. 5B, 5C, and 5D possess a corresponding relationship with FIGS. 4B, 4C, and 4D, respectively.

In some embodiments, as generally shown in FIGS. 5A through 5D, some processing circuits in substrates 502 may be formed using a plurality of well regions 523 and a plurality of doped isolation regions 524, possibly separated by shallow trench insertions (STIs) 522. In some embodiments, each well region 523 may generally refer to doped source and/or drain regions separated by a channel region, individually or collectively dependent upon the context. Circuit structures other than those shown in FIGS. 5A through 5D may be employed in other embodiments.

FIG. 5B depicts CIS IC device 100B of FIG. 4B having upper IC layer 102A and lower IC layers 102B, 102C, and 102D. As shown, upper IC layer 102A includes pixel cells 104, first lower IC layer 102B includes per-pixel circuits 308, second lower IC layer 102C includes per-pixel ADCs 408, and third lower IC layer 102D includes ISP 416. Moreover, each of IC layers 102A-102D include substrate 502, one or two dielectric layers 504 proximate substrate 502, conductive structures 510, TSVs 512, and conductive pads 532 to electrically interconnect circuits of IC layers 102A-102D.

FIG. 5C illustrates CIS IC device 100C of FIG. 4C having upper IC layer 102A and lower IC layers 102B, 102C, and 102D. As depicted, upper IC layer 102A includes pixel cells 104, first lower IC layer 102B includes memory 404, second lower IC layer 102C includes column ADCs 406, and third lower IC layer 102D includes ISP 416. In some embodiments, memory 404 may include a plurality of storage regions 546 disposed in substrate 502 of first lower IC layer 102B for storing electrical charge representing stored data, such as digital image data. Each of IC layers 102A-102D includes substrate 502, one or two dielectric layers 504 proximate substrate 502, conductive structures 510, TSVs 512, and conductive pads 532 to electrically interconnect circuits of IC layers 102A-102D.

FIG. 5D illustrates CIS IC device 100D of FIG. 4D having upper IC layer 102A and lower IC layers 102B, 102C, and 102D. As depicted, upper IC layer 102A includes pixel cells 104, first lower IC layer 102B includes SWIR pixel cells 422, second lower IC layer 102C includes column ADCs 406, and third lower IC layer 102D includes ISP 416. In some embodiments, each SWIR pixel cell 422 may include a photosensitive region 556 disposed in substrate 502 of first lower IC layer 102B for storing electrical charge relative to SWIR light being received at the corresponding photosensitive region 556. Each of IC layers 102A-102D includes substrate 502, one or two dielectric layers 504 proximate substrate 502, conductive structures 510, TSVs 512, and conductive pads 532 to electrically interconnect circuits of IC layers 102A-102D.

FIG. 5E also illustrates CIS IC device 100D of FIG. 4D having upper IC layer 102A and lower IC layers 102B, 102C, and 102D in a manner similar to that of FIG. 5D. As explicitly depicted in FIG. 5E, in some embodiments, SWIR pixel cells 422 may be laterally offset from conductive (e.g., metal) structures 510 employed in upper IC layer 102A and first lower IC layer 102B to facilitate detection of SWIR light by SWIR pixel cells 422.

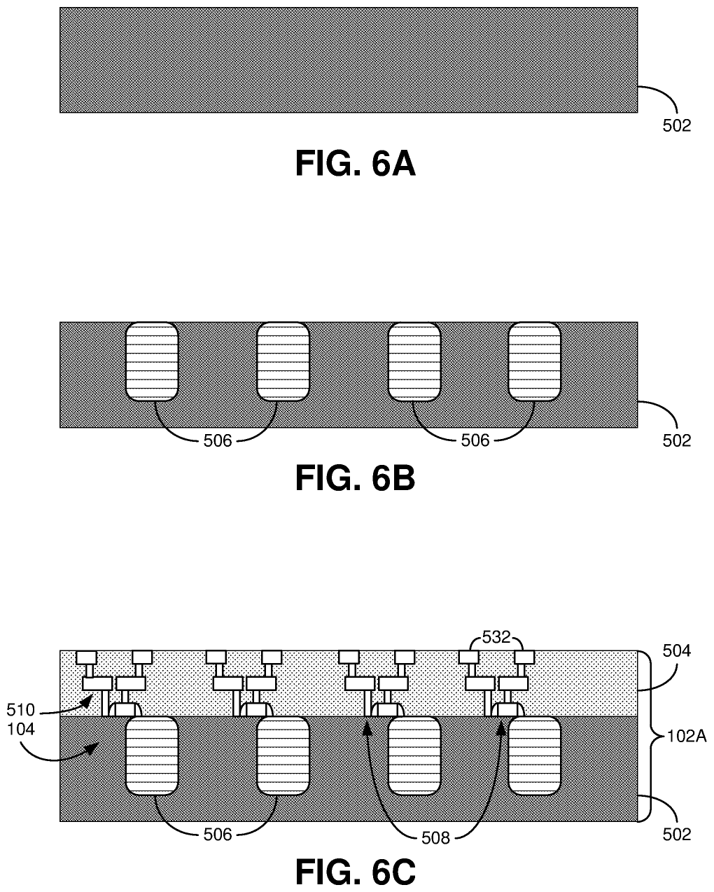

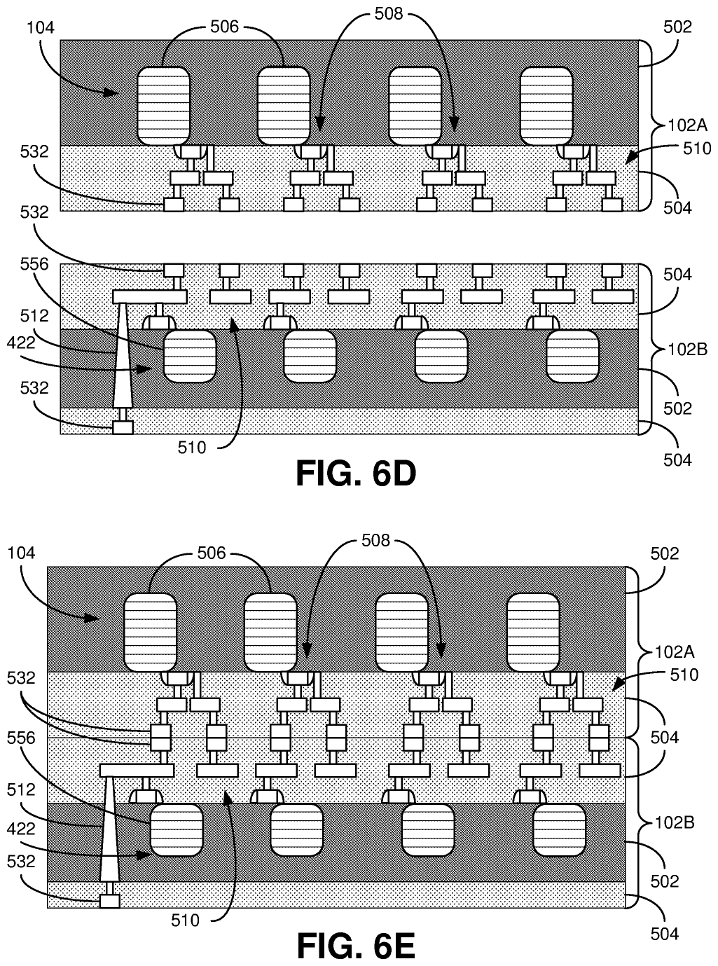

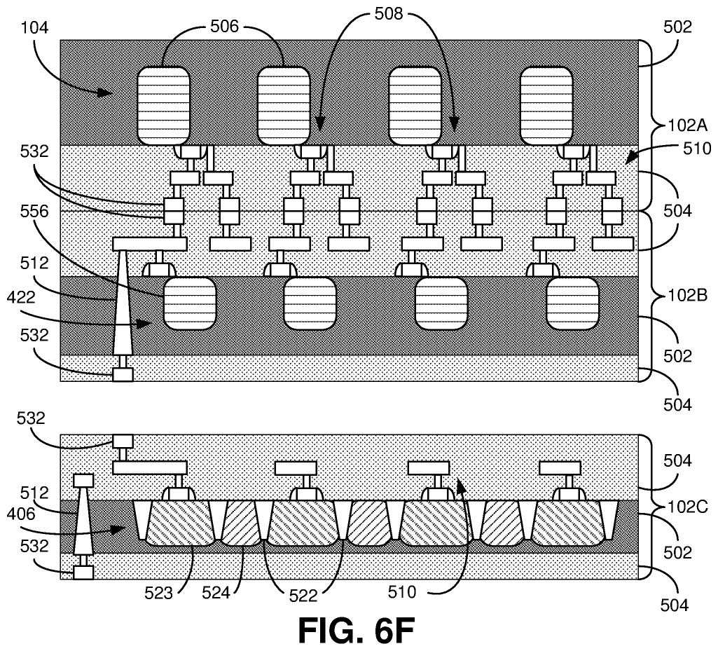

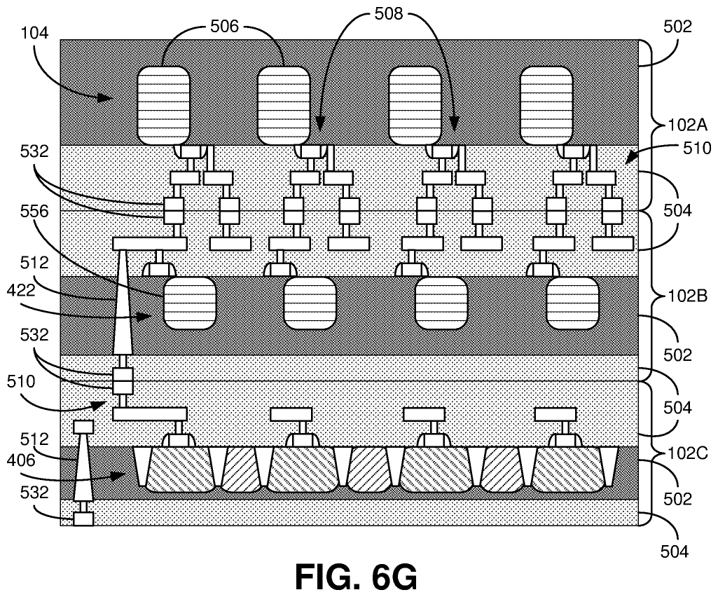

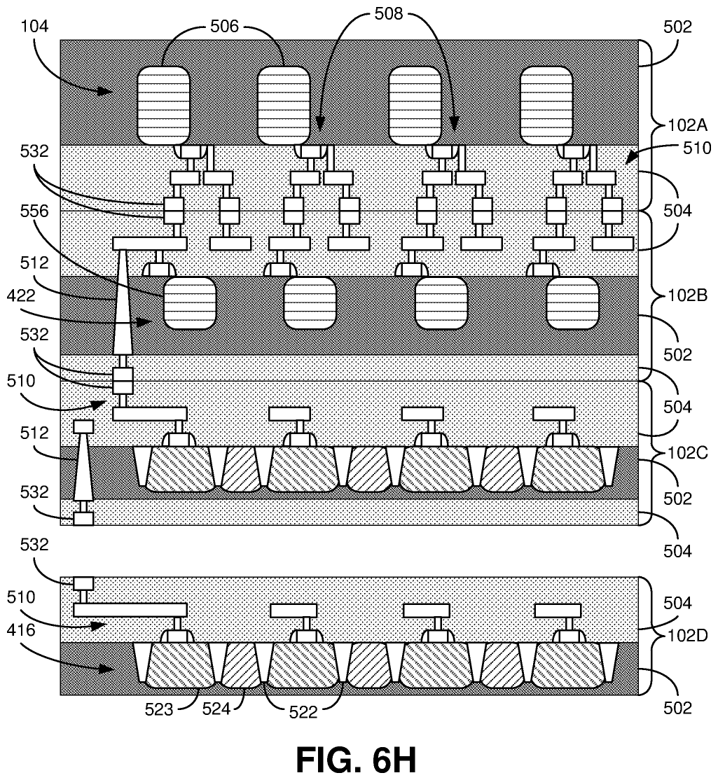

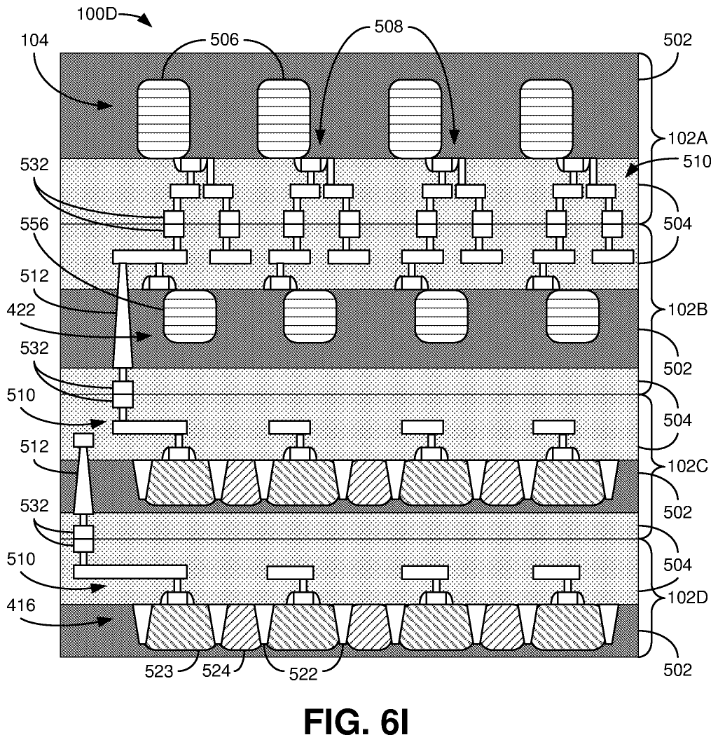

FIGS. 6A through 6I illustrate cross-sectional side views of some embodiments of a CIS multi-die IC device 100D depicted in FIGS. 4D and 5D at various stages of manufacture, according to the present disclosure.

Although FIGS. 6A-6I are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 6A illustrates a first semiconductor substrate 502 (e.g., a silicon substrate) that will serve as a basis for an upper IC layer 102A of CIS IC device 100D.

FIG. 6B illustrates the forming (e.g., implantation or doping) of a plurality of photosensitive regions 506 formed at a first surface of first substrate 502. Each photosensitive region 506 may include a light-absorption region that, in combination with first substrate 502, forms a photodetector (e.g., photodiode) that is sensitive to a light wavelength band. In some embodiments, semiconductor substrate 502 may be p-doped silicon, and photosensitive regions 506 may be portions of substrate 502 that have been implanted or doped with ions to create an n-doped region. In some embodiments, the photodiodes generated by the formation of photosensitive regions 506 may be PN photodiodes (e.g., “pinned” photodiodes) that are sensitive to photons of visible light.

FIG. 6C illustrates the forming (e.g., deposition and/or etching) of a plurality of gate structures and source/drain connections over the first surface of first substrate 502 to create a plurality of transfer transistors 508 that are electrically coupled to the photodetectors resulting in pixel cells 104. In addition, a first dielectric layer 504 is deposited over the first substrate 502, where first dielectric layer 504 has formed therewithin a first conductive structure 510. In some embodiments, first conductive structure 510 includes a plurality of metal layers and interconnecting vias. Further, at a first surface of first dielectric layer 504, a first plurality of conductive pads 532 are formed (e.g., deposited) such that first conductive pads 532 are conductively connected to transfer transistors 508 by way of first conductive structure 510. In some embodiments, the first plurality of conductive pads 532 are embedded in the first surface of first dielectric layer 504 such that the first plurality of conductive pads 532 form a planar surface with the first surface of first dielectric layer 504.

FIG. 6D illustrates the forming of a first lower IC layer 102B that is formed in a similar manner to that of upper IC layer 102A. Fabrication of first lower IC layer 102B begins with a second substrate 502 in which a plurality of SWIR photosensitive regions 556 are formed (e.g., by implantation) at a first surface of second substrate 502. Each photosensitive region 556 may include a light-absorption region that, in combination with second substrate 502, forms a photodetector (e.g., photodiode) that is sensitive to a light wavelength band. In some embodiments, second semiconductor substrate 502 may be p-doped silicon, and photosensitive regions 556 may be portions of second substrate 502 that have been implanted or doped with ions to create an n-doped region. In some embodiments, the photodiodes generated by the formation of photosensitive regions 556 may be PN photodiodes that are sensitive to photons of SWIR light.

Also in FIG. 6D, a plurality of gate structures and source/drain connections is formed (e.g., deposited and/or etched) over the first surface of second substrate 502 to create a plurality of transfer transistors 508 that are electrically coupled to the photodetectors to form SWIR pixel cells 422. In addition, a second dielectric layer 504 is deposited over the second substrate 502, where second dielectric layer 504 has formed therewithin a second conductive structure 510. In some embodiments, second conductive structure 510 includes a plurality of metal layers and interconnecting vias. Further, at a first surface of second dielectric layer 504, a plurality of second conductive pads 532 are formed (e.g., deposited) such that second conductive pads 532 are conductively connected to transfer transistors 508 by way of second conductive structure 510.

Further, in some embodiments, formed (e.g., etched and filled) within second substrate 502 via a second surface opposite the first surface of second substrate 502 is a first plurality of TSVs 512 that are conductively coupled to second conductive structure 510. Formed over the second surface of second substrate 502 is a third dielectric layer 504. Also, formed at a second surface of third dielectric layer 504 opposite a first surface of third dielectric layer 504 adjacent the second surface of second substrate 502 is a third plurality of conductive pads 532 that are conductively connected to the first plurality of TSVs 512 and, in turn, to second conductive structure 510.

In some embodiments, the second and third plurality of conductive pads 532 each form respective planar surfaces with the first surfaces of second and third dielectric layers 504, respectively.

FIG. 6E illustrates the joining (e.g., bonding) of upper IC layer 102A and first lower IC layer 102B by way of first and second dielectric layers 504 and corresponding first and second pluralities of conductive pads 532. In some embodiments, the bonding may include direct bond interconnect (DBI) or other methods or operations of bonding together dielectric layers and associated conductive pads. For example, such bonding may combine a dielectric bond of first and second dielectric layers 504 (e.g., silicon oxide, such as silicon dioxide) by way of dielectric-to-dielectric bonding (e.g., at room temperature). Thereafter, in some embodiments, heat may be applied to compress the first and second pluralities of conductive pads 532 together to create direct connections therebetween. In some embodiments, such internal compression is possible by way of a coefficient of thermal expansion (CTE) of the first and second pluralities of conductive pads 532 being greater than a CTE of first and second dielectric layers 504.

FIG. 6F illustrates the fabrication of second lower IC layer 102C that carries column ADCs 406. Second lower IC layer 402C includes a third substrate 502 and fourth (upper) and fifth (lower) dielectric layers 504. In some embodiments, column ADCs 406 may be constructed using a plurality of well regions 523 and a plurality of doped isolation regions 524, possibly separated by STIs 522, as described above. Within fourth dielectric layer 504 is formed a fourth conductive structure 510 conductively coupling a fourth plurality of conductive pads 532 at a first surface of fourth dielectric layer 504 opposite a second surface of fourth dielectric layer 504 adjacent a first (upper) surface of third substrate 502 to column ADCs 406. Fourth conductive structure 510 may also be coupled by way of a second plurality of TSVs 512 to a fifth plurality of conductive pads 532 at a first surface of fifth dielectric layer 504 opposite a second surface of fifth dielectric layer 504 adjacent a second surface of third substrate 502.

FIG. 6G illustrates the joining (e.g., bonding) of first lower IC layer 102B and second lower IC layer 102C by way of third and fourth dielectric layers 504 and corresponding third and fourth pluralities of conductive pads 532. In some embodiments, the bonding may include DBI or other bonding methods, as described above.

FIG. 6H illustrates the fabrication of third lower IC layer 102D that carries ISP 416. Second lower IC layer 402C includes a fourth substrate 502 and sixth dielectric layer 504. In some embodiments, ISP 416 may be constructed using a plurality of well regions 523 and a plurality of doped isolation regions 524, possibly separated by STIs 522, as described above. Within sixth dielectric layer 504 are formed a sixth conductive structure 510 conductively coupling a sixth plurality of conductive pads 532 at a first surface of sixth dielectric layer 504 opposite a second surface of sixth dielectric layer 504 adjacent a first (upper) surface of fourth substrate 502 to ISP 416.

FIG. 6I illustrates the joining (e.g., bonding) of second lower IC layer 102C and third lower IC layer 102D by way of fifth and sixth dielectric layers 504 and corresponding fifth and sixth pluralities of conductive pads 532. In some embodiments, the bonding may include DBI or other bonding methods, as described above.

While FIGS. 6A through 6I indicate a particular order in which CIS IC device 100D may be fabricated, other orders of operation are possible in other embodiments. For example, all four IC layers 102A-102D may be individually fabricated prior to bonding. Further, in some embodiments, the order of bonding of the IC layers 102A-102D may be performed in a different order, such as first bonding together first lower IC layer 102B and second lower IC layer 102C, or second lower IC layer 102C and third lower IC layer 102D.

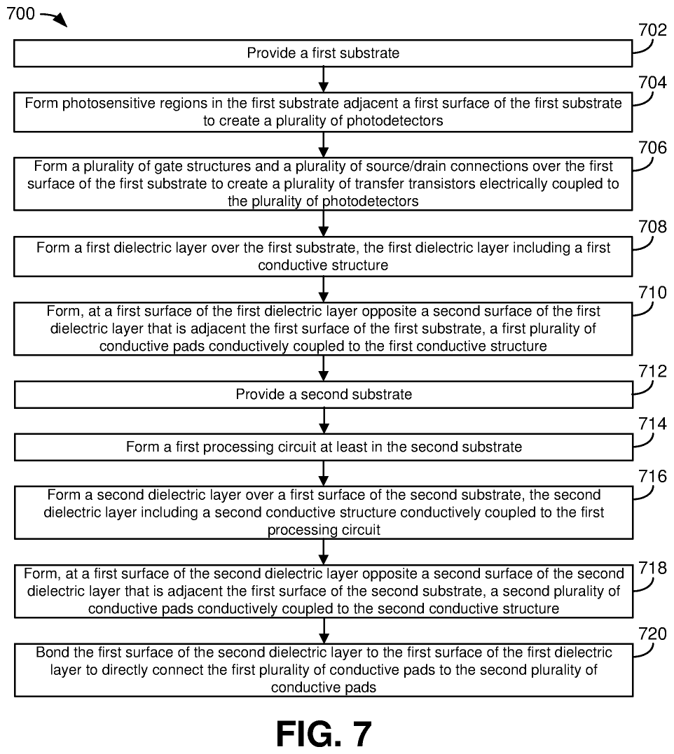

FIG. 7 illustrates a methodology 700 of forming a CIS multi-die IC device (e.g., CIS IC devices 100, 100A-100D) in accordance with some embodiments. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

Acts 702 through 720 may correspond, for example, to the structure previously illustrated in FIGS. 6A through 6E in some embodiments. At Act 702, for example, a first substrate (e.g., first substrate 502 of FIG. 6A) is provided. FIG. 6A illustrates a cross-sectional view of some embodiments corresponding to Act 702.

At Act 704, photosensitive regions (e.g., photosensitive regions 506 of FIG. 6B) are formed in the first substrate adjacent a first surface of the first substrate to create a plurality of photodetectors (e.g., photodetector 202 of FIG. 2A or photodiode 302 of FIGS. 2B, 3A, and 3B). FIG. 6B illustrates a cross-sectional view of some embodiments corresponding to Act 704.

At Act 706, a plurality of gate structures and a plurality of source/drain connections are formed over the first substrate to create a plurality of transfer transistors (e.g., transfer transistor 204 of FIGS. 2A, 2B, 3A, and 3B) electrically coupled to the plurality of photodetectors. In some embodiments, the transfer transistors and photodetectors form a plurality of pixel cells (e.g., pixel cells 104 of FIGS. 2A, 2B, 3A, 3B, and 6C). Further, at Act 708, a first dielectric layer (e.g., first dielectric layer 504 of FIG. 6C) is formed over the first substrate, the first dielectric layer including a first conductive structure (e.g., first conductive structure 510 of FIG. 6C). At Act 710, a first plurality of conductive pads (e.g., first plurality of conductive pads 532 of FIG. 6C) conductively coupled to the first conductive structure are formed at a first surface of the first dielectric layer opposite a second surface of the first dielectric layer that is adjacent the first surface of the first substrate. FIG. 6C illustrates a cross-sectional view of some embodiments corresponding to Acts 706, 708, and 710.

At Act 712, a second substrate (e.g., second substrate 502 of FIG. 6D) is provided. Thereafter, at Act 714, a first processing circuit (e.g., SWIR pixel cells 422 of FIG. 6D) is formed at least in the second substrate. Also, at Act 716, a second dielectric layer (e.g. second dielectric layer 504 of FIG. 6D) is formed over a first surface of the second substrate, the second dielectric layer including a second conductive structure (e.g., second conductive structure 510 of FIG. 6D) conductively coupled to the first processing circuit. At Act 718, a second plurality of conductive pads (e.g., second plurality of conductive pads 532 of FIG. 6D) conductively coupled to the second conductive structure are formed at a first surface of the second dielectric layer opposite a second surface of the second dielectric layer that is adjacent the first surface of the second substrate. FIG. 6D illustrates a cross-sectional view of some embodiments corresponding to Acts 712, 714, 716, and 718.

At Act 720, the first surface of the second dielectric layer is bonded (e.g., using DBI or other bonding methods) to the first surface of the first dielectric layer to directly connect the first plurality of conductive pads to the second plurality of conductive pads. FIG. 6E illustrates a cross-sectional view of some embodiments corresponding to Act 720.

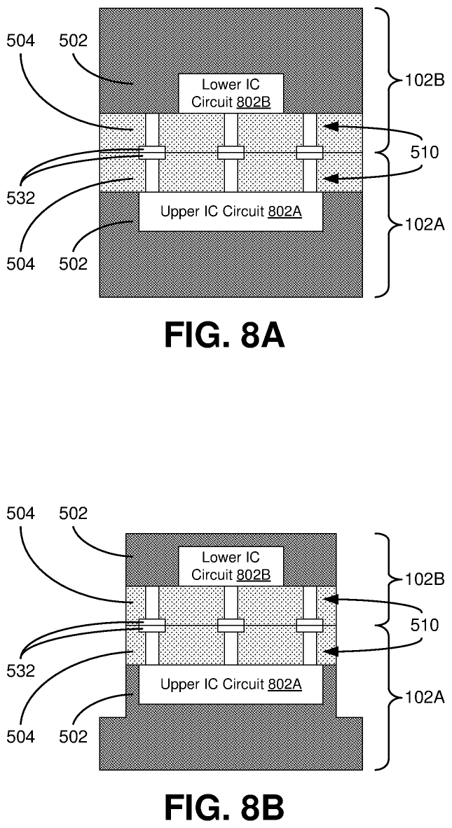

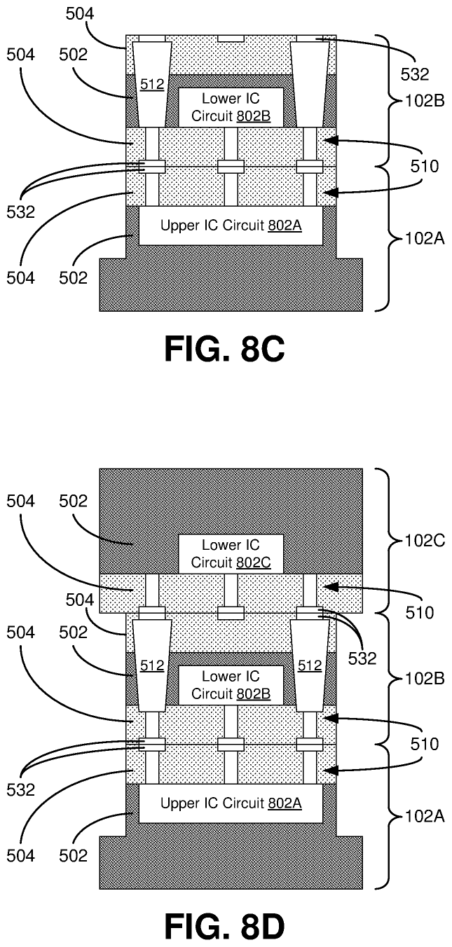

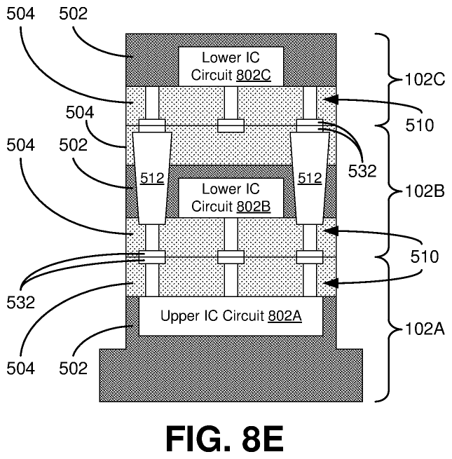

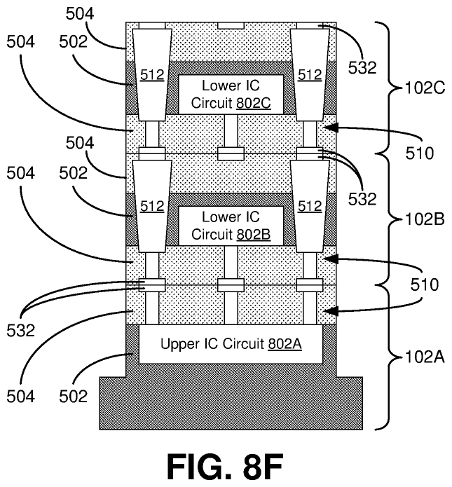

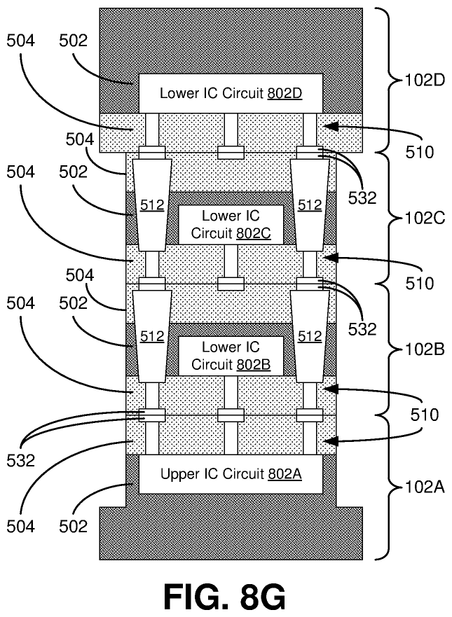

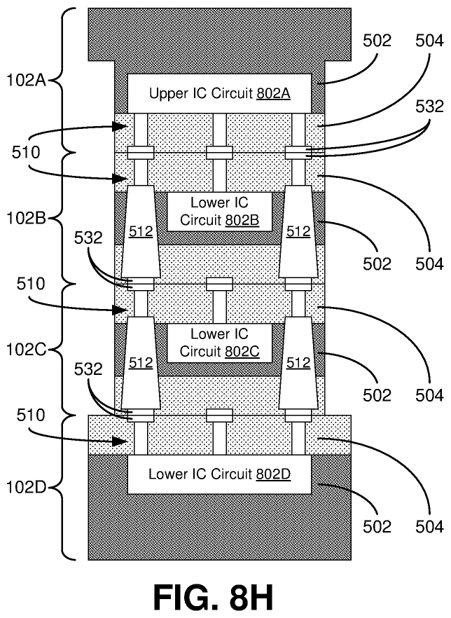

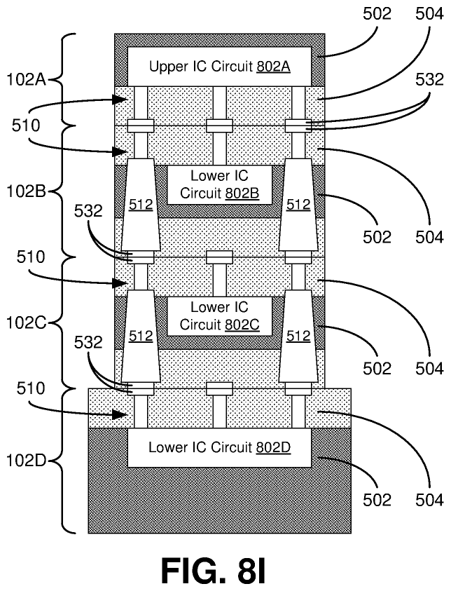

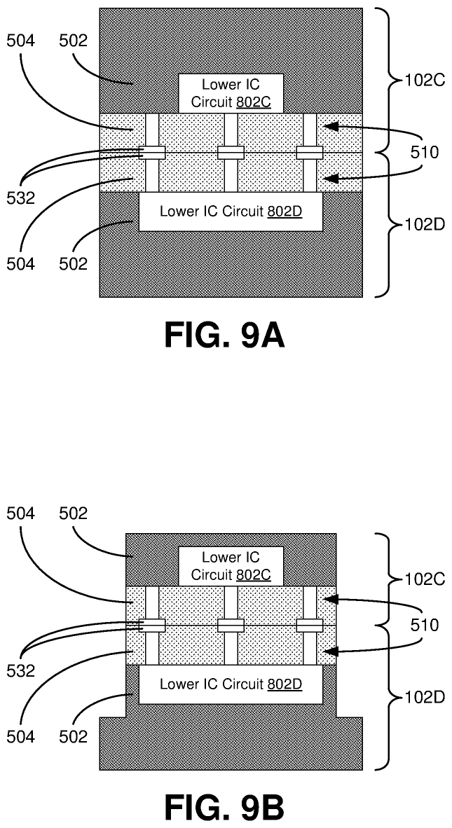

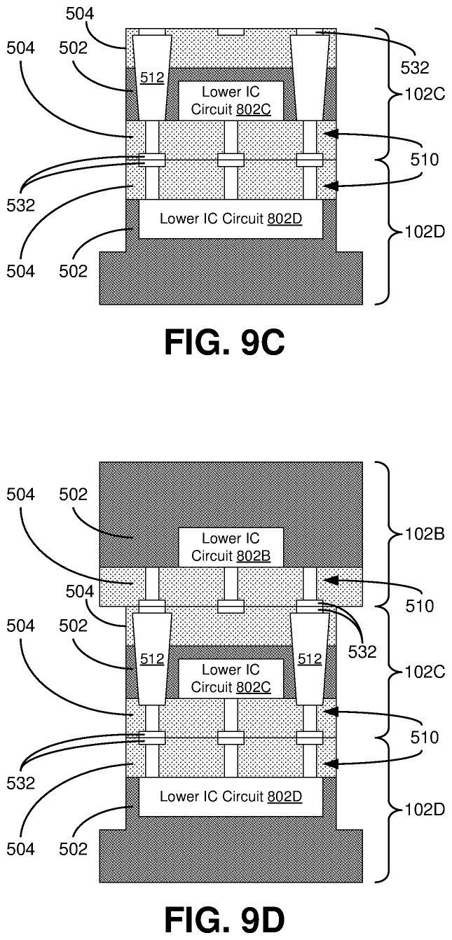

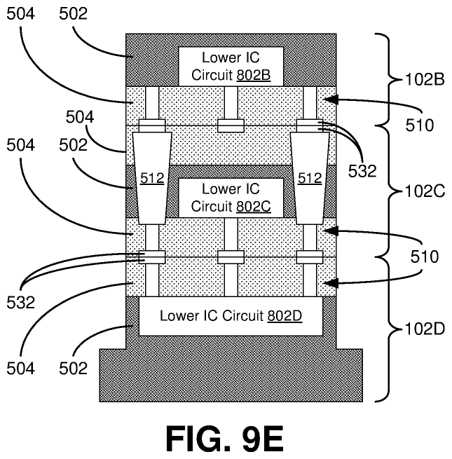

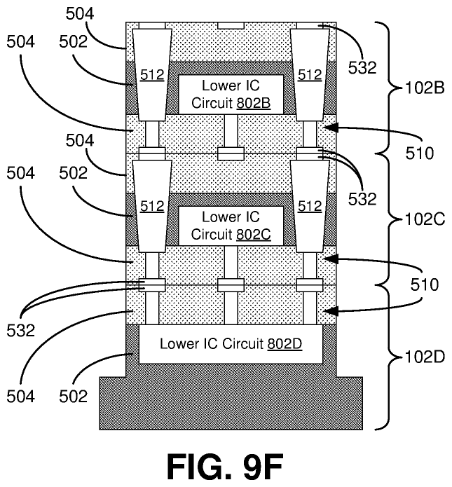

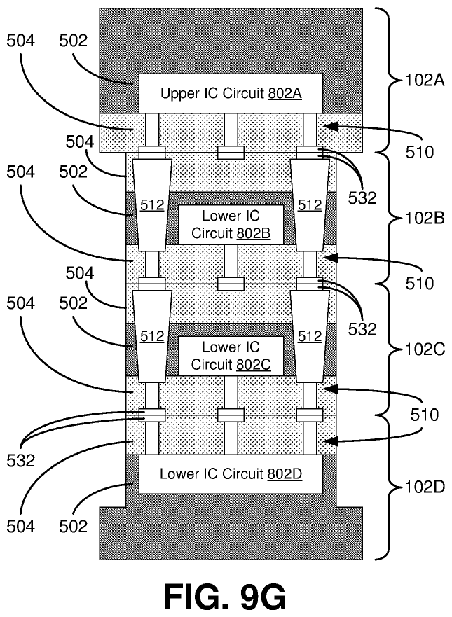

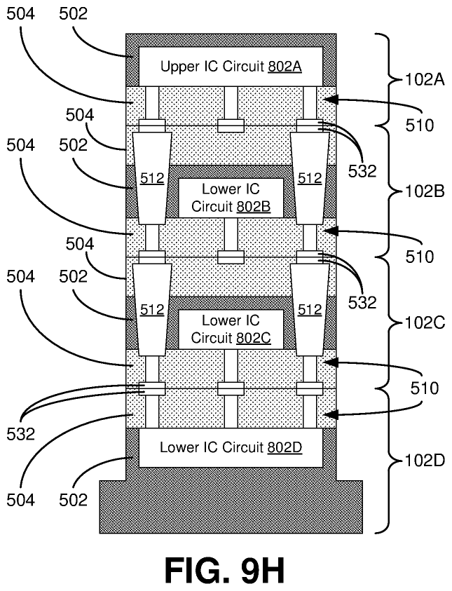

FIGS. 8A through 8I and FIGS. 9A through 9H illustrate corresponding schematic cross-sectional side views of some embodiments of a four-layer CIS multi-die IC device at various stages of manufacture, according to the present disclosure. FIGS. 8A through 8I and FIGS. 9A through 9H focus on bonding and substrate thinning aspects of fabrication, and thus omit some structural and processing details of FIGS. 6A through 6I and FIG. 7 to simplify the following discussion. However, various aspects of FIGS. 6A through 6I, FIG. 7, FIGS. 8A through 8I, and FIGS. 9A through 9H may be combined in other embodiments. Moreover, FIGS. 8A through 8I and FIGS. 9A through 9H may be applied to any of the CIS multi-die IC devices described above, such as those corresponding to FIGS. 4A through 4D and FIGS. 5A through 5E.

More specifically, FIGS. 8A through 8I illustrate schematic cross-sectional side views of some embodiments of a four-layer CIS multi-die IC device at various stages of manufacture, beginning with upper IC layer 102A, according to the present disclosure. For example, FIG. 8A illustrates the joining (e.g., bonding) of upper IC layer 102A (e.g., including an upper IC circuit 802A that may include the plurality of photosensitive regions 506 of pixel cells 104 of FIG. 4A) and first lower IC layer 102B (e.g., including a first lower IC circuit 802B that may include per-pixel circuits 308 and in-pixel circuit 310 of FIG. 4A) by way of first and second dielectric layers 504 and corresponding first and second pluralities of conductive pads 532. In some embodiments, the bonding may include DBI or other bonding methods, as described above with respect to FIG. 6E. Also, in some embodiments, conductive structures 510 may electrically couple upper IC circuit 802A and first lower IC circuit 802B to corresponding one or more conductive pads 532.

FIG. 8B illustrates the vertical thinning (e.g., via chemical-mechanical planarization (CMP)) of a portion of substrate 502 of first lower IC layer 102B (e.g., in preparation for forming one or more TSVs therein). In some embodiments, a lateral narrowing of portions of substrate 502 and dielectric layer 504 of upper IC layer 102A and first lower IC layer 102B may also be performed.

FIG. 8C illustrates the forming (e.g., deposition) of a third dielectric layer 504 for first lower IC layer 102B, along with the forming (e.g., etching and filling) of one or more TSVs 512 and one or more conductive pads 532 therein.

FIG. 8D illustrates the joining (e.g., bonding) of first lower IC layer 102B and second lower IC layer 102C (e.g., including a second lower IC circuit 802C that may include column ADC 406 of FIG. 4A) by way of third and fourth dielectric layers 504 and corresponding third and fourth pluralities of conductive pads 532. In some embodiments, the bonding may include DBI or other applicable bonding methods. Also, in some embodiments, conductive structures 510 may electrically couple second lower IC circuit 802C to corresponding one or more conductive pads 532.

FIG. 8E illustrates the vertical thinning (e.g., via CMP) of a portion of substrate 502 of second lower IC layer 102C (e.g., in preparation for forming one or more TSVs therein). In some embodiments, a lateral narrowing of portions of substrate 502 and dielectric layer 504 of second lower IC layer 102C may also be performed.

FIG. 8F illustrates the forming (e.g., deposition) of a fifth dielectric layer 504 for second lower IC layer 102C, along with the forming (e.g., etching and filling) of one or more TSVs 512 and one or more conductive pads 532 therein.

FIG. 8G illustrates the joining (e.g., bonding) of second lower IC layer 102C and third lower IC layer 102D (e.g., including a third lower IC circuit 802D that may include ISP 416 of FIG. 4A) by way of fifth and sixth dielectric layers 504 and corresponding fifth and sixth pluralities of conductive pads 532. In some embodiments, the bonding may include DBI or other applicable bonding methods. Also, in some embodiments, conductive structures 510 may electrically couple third lower IC circuit 802D to corresponding one or more conductive pads 532.

FIG. 8H illustrates the inversion or flipping of the assembly of FIG. 8G so that upper IC layer 102A is uppermost.

FIG. 8I illustrates the vertical thinning (e.g., via CMP) of a portion of substrate 502 of upper IC layer 102A (e.g., in preparation for processing an upper surface of substrate 502, such as to apply lenses, optical filters, and/or the like).

FIGS. 9A through 9H illustrate schematic cross-sectional side views of some embodiments of another four-layer CIS multi-die IC device at various stages of manufacture, beginning with third lower IC layer 102D, according to the present disclosure.

For example, FIG. 9A illustrates the joining (e.g., bonding) of third lower IC layer 102D (e.g., including third lower IC circuit 802D) and second lower IC layer 102C (e.g., including second lower IC circuit 802C) by way of first and second dielectric layers 504 and corresponding first and second pluralities of conductive pads 532. In some embodiments, the bonding may include DBI or other bonding methods. Also, in some embodiments, conductive structures 510 may electrically couple third lower IC circuit 802D and second lower IC circuit 802C to corresponding one or more conductive pads 532.

FIG. 9B illustrates the vertical thinning (e.g., via CMP) of a portion of substrate 502 of second lower IC layer 102C (e.g., in preparation for forming one or more TSVs therein). In some embodiments, a lateral narrowing of portions of substrate 502 and dielectric layer 504 of third lower IC layer 102D and second lower IC layer 102C may also be performed.

FIG. 9C illustrates the forming (e.g., deposition) of a third dielectric layer 504 for second lower IC layer 102C, along with the forming (e.g., etching and filling) of one or more TSVs 512 and one or more conductive pads 532 therein.

FIG. 9D illustrates the joining (e.g., bonding) of second lower IC layer 102C and first lower IC layer 102B (e.g., including first lower IC circuit 802B) by way of third and fourth dielectric layers 504 and corresponding third and fourth pluralities of conductive pads 532. In some embodiments, the bonding may include DBI or other bonding methods. Also, in some embodiments, conductive structures 510 may electrically couple first lower IC circuit 802B to corresponding one or more conductive pads 532.

FIG. 9E illustrates the vertical thinning (e.g., via CMP) of a portion of substrate 502 of first lower IC layer 102B (e.g., in preparation for forming one or more TSVs therein). In some embodiments, a lateral narrowing of portions of substrate 502 and dielectric layer 504 of first lower IC layer 102B may also be performed.

FIG. 9F illustrates the forming (e.g., deposition) of a fifth dielectric layer 504 for first lower IC layer 102B, along with the forming (e.g., etching and filling) of one or more TSVs 512 and one or more conductive pads 532 therein.

FIG. 9G illustrates the joining (e.g., bonding) of first lower IC layer 102B and upper IC layer 102A (e.g., including upper IC circuit 802A) by way of fifth and sixth dielectric layers 504 and corresponding fifth and sixth pluralities of conductive pads 532. In some embodiments, the bonding may include DBI or other bonding methods. Also, in some embodiments, conductive structures 510 may electrically couple upper IC circuit 802A to corresponding one or more conductive pads 532.

FIG. 9H illustrates the vertical thinning (e.g., via CMP) of a portion of substrate 502 of upper IC layer 102A (e.g., in preparation for processing a surface of substrate 502, such as to apply lenses, optical filters, and/or the like). In some embodiments, a lateral narrowing of portions of substrate 502 and dielectric layer 504 of upper IC layer 102A may also be performed.

Some embodiments relate to an IC device. The IC device includes an upper IC layer and a lower IC layer. The upper IC layer includes a plurality of pixel cells, each of the plurality of pixel cells including a photodetector and a transfer transistor electrically coupled to the photodetector and configured to transfer electrical charge collected at the photodetector. The upper IC layer also includes a first plurality of conductive pads disposed at a lower surface of the upper IC layer, each of the first plurality of conductive pads carrying an indication of the electrical charge transferred by the transfer transistor of one or more of the plurality of pixel cells. The lower IC layer includes a second plurality of conductive pads disposed at an upper surface of the first lower IC layer, the upper surface of the first lower IC layer lying adjacent the lower surface of the upper IC layer, each of the second plurality of conducive pads directly contacting a corresponding one of the first plurality of conductive pads. The lower IC layer also includes a first processing circuit conductively coupled to the second plurality of conductive pads, the first processing circuit configured to process signals carried via the first and second pluralities of conductive pads.

Some embodiments relate to another IC device. The IC device includes an upper IC layer and a lower IC layer. The upper IC layer includes a first substrate, a first dielectric layer disposed at a lower surface of the first substrate, and a plurality of pixel cells. Each of the plurality of pixel cells includes a photodetector disposed in the first substrate and a transfer transistor electrically coupled to the photodetector and including a gate and a source/drain connection disposed in the first dielectric layer. The upper IC layer also includes a first conductive structure disposed in the first dielectric layer and connecting the gate of the transfer transistor of each of the plurality of pixel cells to a corresponding one of a first plurality of conductive pads disposed at a lower surface of the first dielectric layer. The lower IC layer includes a second dielectric layer disposed below and adjacent the lower surface of the first dielectric layer, a second substrate disposed below the second dielectric layer, and a second plurality of conductive pads disposed at an upper surface of the second dielectric layer. Each of the second plurality of conductive pads directly contacts a corresponding one of the first plurality of conductive pads. The lower IC layer further includes a first processing circuit disposed in at least the second substrate. The lower IC layer also includes a second conductive structure disposed in the second dielectric layer and conductively coupling the second plurality of conductive pads to the first processing circuit.

Some embodiments relate to a method. The method includes: providing a first substrate; forming a plurality of photosensitive regions in the first substrate adjacent a first surface of the first substrate to create a plurality of photodetectors; forming a plurality of gate structures and a plurality of source/drain connections over the first surface of the first substrate to create a plurality of transfer transistors electrically coupled to the plurality of photodetectors; forming a first dielectric layer over the first substrate, the first dielectric layer including a first conductive structure; forming, at a first surface of the first dielectric layer opposite a second surface of the first dielectric layer that is adjacent the first surface of the first substrate, a first plurality of conductive pads conductively coupled to the first conductive structure. The method further includes providing a second substrate; forming a first processing circuit at least in the second substrate; forming a second dielectric layer over a first surface of the second substrate, the second dielectric layer including a second conductive structure conductively coupled to the first processing circuit; and forming, at a first surface of the second dielectric layer opposite a second surface of the second dielectric layer that is adjacent the first surface of the second substrate, a second plurality of conductive pads conductively coupled to the second conductive structure. The method also includes bonding the first surface of the second dielectric layer to the first surface of the first dielectric layer to directly connect the first plurality of conductive pads to the second plurality of conductive pads.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
an upper IC layer comprising:
a plurality of pixel cells, each of the plurality of pixel cells comprising:
a photodetector; and
a transfer transistor electrically coupled to the photodetector and configured to transfer electrical charge collected at the photodetector; and
a first plurality of conductive pads disposed at a lower surface of the upper IC layer, each of the first plurality of conductive pads carrying an indication of the electrical charge transferred by the transfer transistor of one or more of the plurality of pixel cells; and
a first lower IC layer comprising:
a second plurality of conductive pads disposed at an upper surface of the first lower IC layer, the upper surface of the first lower IC layer lying adjacent the lower surface of the upper IC layer, each of the second plurality of conductive pads directly contacting a corresponding one of the first plurality of conductive pads; and
a first processing circuit conductively coupled to the second plurality of conductive pads, the first processing circuit configured to process signals carried via the first and second pluralities of conductive pads.

2. The IC device of claim 1, wherein:
the upper IC layer further comprises:
a plurality of per-pixel circuits, each of the plurality of per-pixel circuits being configured to forward the indication of the electrical charge transferred by the transfer transistor of a corresponding one of the plurality of pixel cells according to at least one timing signal to generate a plurality of timed indications, each of the plurality of timed indications comprising a timed indication of the electrical charge transferred by the transfer transistor of a corresponding one of the plurality of pixel cells; and
an in-pixel circuit configured to process the plurality of timed indications to generate image data; and
the first processing circuit comprises an application-specific integrated circuit (ASIC) configured to process the image data.

3. The IC device of claim 2, wherein each of the plurality of per-pixel circuits comprises:
a source follower transistor electrically coupled to the transfer transistor and configured to buffer the transfer transistor from a column bus;
a reset transistor electrically coupled to the source follower transistor to reset the electrical charge transferred by the transfer transistor; and
a row select transistor configured to forward the electrical charge to the column bus according to the at least one timing signal.

4. The IC device of claim 1, wherein:
the first lower IC layer further comprises a third plurality of conductive pads disposed at a lower surface of the first lower IC layer, each of the third plurality of conductive pads carrying a signal generated by the first processing circuit; and
the IC device further comprises a second lower IC layer comprising:
a fourth plurality of conductive pads disposed at an upper surface of the second lower IC layer, the upper surface of the second lower IC layer lying adjacent the lower surface of the first lower IC layer, each of the fourth plurality of conductive pads directly contacting a corresponding one of the third plurality of conductive pads; and
a second processing circuit conductively coupled to the fourth plurality of conductive pads, the second processing circuit configured to process the signals generated by the first processing circuit and carried via the third and fourth pluralities of conductive pads.

5. The IC device of claim 4, wherein the first lower IC layer further comprises a plurality of through-substrate vias (TSVs) conductively coupling the first processing circuit to the third plurality of conductive pads.

6. The IC device of claim 4, wherein:
the first processing circuit comprises:
a plurality of per-pixel circuits, each of the plurality of per-pixel circuits being configured to forward the indication of the electrical charge transferred by the transfer transistor of a corresponding one of the plurality of pixel cells according to at least one timing signal to generate a plurality of timed indications, each of the plurality of timed indications comprising a timed indication of the electrical charge transferred by the transfer transistor of a corresponding one of the plurality of pixel cells; and
an in-pixel circuit configured to process the plurality of timed indications to generate image data; and
the second processing circuit comprises an application-specific integrated circuit (ASIC) configured to process the image data.

7. The IC device of claim 6, wherein each of the plurality of per-pixel circuits comprises:
a source follower transistor electrically coupled to the transfer transistor and configured to buffer the transfer transistor from a column bus;
a reset transistor electrically coupled to the source follower transistor to reset the electrical charge transferred by the transfer transistor; and
a row select transistor configured to forward the electrical charge to the column bus according to the at least one timing signal.

8. The IC device of claim 4, wherein:
the second lower IC layer further comprises a fifth plurality of conductive pads disposed at a lower surface of the second lower IC layer, each of the fifth plurality of conductive pads carrying a signal generated by the second processing circuit; and
the IC device further comprises a third lower IC layer comprising:
a sixth plurality of conductive pads disposed at an upper surface of the third lower IC layer, the upper surface of the third lower IC layer lying adjacent the lower surface of the second lower IC layer, each of the sixth plurality of conductive pads directly contacting a corresponding one of the fifth plurality of conductive pads; and
a third processing circuit conductively coupled to the sixth plurality of conductive pads, the third processing circuit configured to process signals generated by the second processing circuit and carried via the fifth and sixth pluralities of conductive pads.

9. The IC device of claim 8, wherein the second lower IC layer further comprises a plurality of through-substrate vias (TSVs) conductively coupling the second processing circuit to the fifth plurality of conductive pads.

10. The IC device of claim 8, wherein:
the first processing circuit comprises:
a plurality of per-pixel circuits, each of the plurality of per-pixel circuits being configured to forward the indication of the electrical charge transferred by the transfer transistor of a corresponding one of the plurality of pixel cells according to at least one timing signal to generate a plurality of timed indications, each of the plurality of timed indications comprising a timed indication of the electrical charge transferred by the transfer transistor of a corresponding one of the plurality of pixel cells; and
an in-pixel circuit configured to process the plurality of timed indications to generate analog image data for each row of a plurality of rows of the plurality of pixel cells;
the second processing circuit comprises a column analog-to-digital converter (ADC) circuit configured to generate digital image data for each row of the plurality of rows of the plurality of pixel cells based on the analog image data; and
the third processing circuit comprises an image signal processor (ISP) configured to process the digital image data.

11. The IC device of claim 8, wherein:
the first processing circuit comprises:
a plurality of per-pixel circuits, each of the plurality of per-pixel circuits being configured to forward the indication of the electrical charge transferred by the transfer transistor of a corresponding one of the plurality of pixel cells according to at least one timing signal to generate a plurality of timed indications, each of the plurality of timed indications comprising a timed indication of the electrical charge transferred by the transfer transistor of a corresponding one of the plurality of pixel cells; and
an in-pixel circuit configured to process the plurality of timed indications to generate analog image data for each of the plurality of pixel cells;
the second processing circuit comprises a per-pixel analog-to-digital converter (ADC) circuit configured to generate digital image data for each of the plurality of pixel cells based on the analog image data; and
the third processing circuit comprises an image signal processor (ISP) configured to process the digital image data.

12. The IC device of claim 8, wherein:
the upper IC layer further comprises:
a plurality of per-pixel circuits, each of the plurality of per-pixel circuits being configured to forward the indication of the electrical charge transferred by the transfer transistor of a corresponding one of the plurality of pixel cells according to at least one timing signal to generate a plurality of timed indications, each of the plurality of timed indications comprising a timed indication of the electrical charge transferred by the transfer transistor of a corresponding one of the plurality of pixel cells; and
an in-pixel circuit configured to process the plurality of timed indications to generate analog image data for each of the plurality of pixel cells;
the first processing circuit comprises a memory configured to store digital image data for each of the plurality of pixel cells based on the analog image data;
the second processing circuit comprises a column analog-to-digital converter (ADC) circuit configured to generate the digital image data for each row of a plurality of rows of the plurality of pixel cells based on the analog image data; and
the third processing circuit comprises an image signal processor (ISP) configured to process the digital image data.

13. The IC device of claim 8, wherein:
the upper IC layer further comprises:
a first plurality of per-pixel circuits, each of the first plurality of per-pixel circuits being configured to forward the indication of the electrical charge transferred by the transfer transistor of a corresponding one of the plurality of pixel cells according to at least one timing signal to generate a first plurality of timed indications, each of the first plurality of timed indications comprising a first timed indication of the electrical charge transferred by the transfer transistor of a corresponding one of the plurality of pixel cells; and
a first in-pixel circuit configured to process the first plurality of timed indications to generate analog image data for each of the plurality of pixel cells;
the first processing circuit comprises:
a plurality of infrared pixel cells, wherein each of the plurality of infrared pixel cells comprises:
an infrared photodetector; and
a second transfer transistor electrically coupled to the photodetector and configured to transfer electrical charge collected at the infrared photodetector;
a second plurality of per-pixel circuits, each of the second plurality of per-pixel circuits being configured to forward the indication of the electrical charge transferred by the second transfer transistor of a corresponding one of the plurality of infrared pixel cells according to a second at least one timing signal to generate a second plurality of timed indications, each of the second plurality of timed indications comprising a timed indication of the electrical charge transferred by the second transfer transistor of a corresponding one of the plurality of infrared pixel cells; and
a second in-pixel circuit configured to process the second plurality of timed indications to generate second analog image data for each of the plurality of infrared pixel cells;
the second processing circuit comprises a column analog-to-digital converter (ADC) circuit configured to generate first digital image data for each row of a plurality of rows of the plurality of pixel cells based on the analog image data, and to generate second digital image data for each row of the plurality of rows of the plurality of infrared pixel cells based on the second analog image data; and
the third processing circuit comprises an image signal processor (ISP) configured to process the first digital image data and the second analog image data.

14. An integrated circuit (IC) device, comprising:
an upper IC layer comprising:
a first substrate;
a first dielectric layer disposed at a lower surface of the first substrate;
a plurality of pixel cells, each of the plurality of pixel cells comprising:
a photodetector disposed in the first substrate; and
a transfer transistor electrically coupled to the photodetector and comprising
a gate and a source/drain connection disposed in the first dielectric layer; and
a first conductive structure disposed in the first dielectric layer and connecting the gate of the transfer transistor of each of the plurality of pixel cells to a corresponding one of a first plurality of conductive pads disposed at a lower surface of the first dielectric layer; and
a first lower IC layer comprising:
a second dielectric layer disposed below and adjacent the lower surface of the first dielectric layer;
a second substrate disposed below the second dielectric layer;
a second plurality of conductive pads disposed at an upper surface of the second dielectric layer, each of the second plurality of conductive pads directly contacting a corresponding one of the first plurality of conductive pads;
a first processing circuit disposed in at least the second substrate; and
a second conductive structure disposed in the second dielectric layer and conductively coupling the second plurality of conductive pads to the first processing circuit.

15. The IC device of claim 14, wherein:
the first lower IC layer further comprises:
a third dielectric layer disposed below and adjacent the second substrate;
a third plurality of conductive pads disposed at a lower surface of the third dielectric layer; and
a first plurality of through-substrate vias (TSVs) disposed at least in the second substrate and conductively coupling the third plurality of conductive pads to the second conductive structure; and
the IC device further comprises a second lower IC layer comprising:
a fourth dielectric layer disposed below and adjacent the lower surface of the third dielectric layer;
a third substrate disposed below the fourth dielectric layer;
a fourth plurality of conductive pads disposed at an upper surface of the fourth dielectric layer, each of the fourth plurality of conductive pads directly contacting a corresponding one of the third plurality of conductive pads;
a second processing circuit disposed at least in the third substrate; and
a third conductive structure disposed in the fourth dielectric layer and conductively coupling the fourth plurality of conductive pads to the second processing circuit.

16. The IC device of claim 15, wherein:
the second lower IC layer further comprises:
a fifth dielectric layer disposed below and adjacent the third substrate;
a fifth plurality of conductive pads disposed at a lower surface of the fifth dielectric layer; and
a second plurality of through-substrate vias (TSVs) disposed at least in the third substrate and conductively coupling the fifth plurality of conductive pads to the third conductive structure; and
the IC device further comprises a third lower IC layer comprising:
a sixth dielectric layer disposed below and adjacent the lower surface of the fifth dielectric layer;
a fourth substrate disposed below the sixth dielectric layer;
a sixth plurality of conductive pads disposed at an upper surface of the sixth dielectric layer, each of the sixth plurality of conductive pads directly contacting a corresponding one of the fifth plurality of conductive pads;
a third processing circuit disposed at least in the fourth substrate; and
a fourth conductive structure disposed in the sixth dielectric layer and conductively coupling the sixth plurality of conductive pads to the third processing circuit.

17. A method, comprising:
providing a first substrate;
forming a plurality of photosensitive regions in the first substrate adjacent a first surface of the first substrate to create a plurality of photodetectors;
forming a plurality of gate structures and a plurality of source/drain connections over the first surface of the first substrate to create a plurality of transfer transistors electrically coupled to the plurality of photodetectors;
forming a first dielectric layer over the first substrate, the first dielectric layer including a first conductive structure;
forming, at a first surface of the first dielectric layer opposite a second surface of the first dielectric layer that is adjacent the first surface of the first substrate, a first plurality of conductive pads conductively coupled to the first conductive structure;
providing a second substrate;
forming a first processing circuit at least in the second substrate;
forming a second dielectric layer over a first surface of the second substrate, the second dielectric layer including a second conductive structure conductively coupled to the first processing circuit;
forming, at a first surface of the second dielectric layer opposite a second surface of the second dielectric layer that is adjacent the first surface of the second substrate, a second plurality of conductive pads conductively coupled to the second conductive structure; and
bonding the first surface of the second dielectric layer to the first surface of the first dielectric layer to directly connect the first plurality of conductive pads to the second plurality of conductive pads.

18. The method of claim 17, wherein bonding the first surface of the second dielectric layer to the first surface of the first dielectric layer comprises a bonding operation that bonds the first plurality of conductive pads to the second plurality of conductive pads.

19. The method of claim 17, further comprising:
forming a first plurality of through-substrate vias (TSVs) in at least the second substrate, the first plurality of TSVs being conductively connected to the second conductive structure;
forming a third dielectric layer over a second surface of the second substrate that is opposite the first surface of the second substrate;
forming, at a first surface of the third dielectric layer opposite a second surface of the third dielectric layer that is adjacent the second surface of the second substrate, a third plurality of conductive pads conductively coupled to the first plurality of TSVs;
providing a third substrate;
forming a second processing circuit at least in the third substrate;
forming a fourth dielectric layer over a first surface of the third substrate, the fourth dielectric layer including a third conductive structure conductively coupled to the second processing circuit;
forming, at a first surface of the fourth dielectric layer opposite a second surface of the fourth dielectric layer that is adjacent the first surface of the third substrate, a fourth plurality of conductive pads conductively coupled to the third conductive structure; and
bonding the first surface of the fourth dielectric layer to the first surface of the third dielectric layer to directly connect the fourth plurality of conductive pads to the third plurality of conductive pads.

20. The method of claim 19, further comprising:
forming a second plurality of TSVs in at least the third substrate, the second plurality of TSVs being conductively connected to the third conductive structure;
forming a fifth dielectric layer over a second surface of the third substrate that is opposite the first surface of the third substrate;
forming, at a first surface of the fifth dielectric layer opposite a second surface of the fourth dielectric layer that is adjacent the second surface of the third substrate, a fifth plurality of conductive pads conductively coupled to the second plurality of TSVs;
providing a fourth substrate;
forming a third processing circuit at least in the fourth substrate;
forming a sixth dielectric layer over a first surface of the fourth substrate, the sixth dielectric layer including a fourth conductive structure;
forming, at a first surface of the sixth dielectric layer opposite a second surface of the sixth dielectric layer that is adjacent the first surface of the fourth substrate, a sixth plurality of conductive pads conductively coupled to the fourth conductive structure; and
bonding the first surface of the sixth dielectric layer to the first surface of the fifth dielectric layer to directly connect the sixth plurality of conductive pads to the fifth plurality of conductive pads.
